(19) United States
(12) Patent Application Publication
(10) Pub. No.: US 2025/0380394 A1
(43) Pub. Date: Dec. 11, 2025

(54) SEMICONDUCTOR MEMORY DEVICE

(71) Applicant: Samsung Electronics Co., Ltd., Suwon-si (KR)

(72) Inventors: Jee Woong KIM, Suwon-si (KR); Yun Suk NAM, Suwon-si (KR); Jae Hoon SHIN, Suwon-si (KR); Hae In SHIN, Suwon-si (KR); In Ho YEO, Suwon-si (KR)

(73) Assignee: Samsung Electronics Co., Ltd., Suwon-si (KR)

(21) Appl. No.: 19/016,156

(22) Filed: Jan. 10, 2025

(30) Foreign Application Priority Data
Jun. 11, 2024 (KR) 10-2024-0075428

(51) Int. Cl. H10B 10/00; G11C 11/412; G11C 11/419

(52) U.S. Cl. CPC H10B 10/12; G11C 11/412; G11C 11/419

(57) ABSTRACT

A semiconductor device including an SRAM (Static Random-Access Memory) element is provided. The semiconductor device includes a substrate, a first power supply line and a second power supply line to which different voltages are applied, on the substrate, a word line which extends in a first direction, on the substrate, a bit line and a complementary bit line which extend in parallel in a second direction intersecting the first direction, on the substrate, and a first cell and a second cell which are arranged along the second direction, on the substrate, wherein the first cell includes a first inverter and a second inverter connected in parallel between the first power supply line and the second power supply line to form a latch circuit, a first pass transistor which connects an output node of the first inverter and the bit line, and a second pass transistor which connects an output node of the second inverter and the complementary bit line, the word line is connected to a gate of the first pass transistor and a gate of the second pass transistor, the second cell includes a first buffer transistor which connects the second power supply line and the bit line, and a second buffer transistor which connects the second power supply line and the complementary bit line, the bit line is connected to a gate of the first buffer transistor, and the complementary bit line is connected to a gate of the second buffer transistor.

### CROSS-REFERENCE TO RELATED APPLICATION

This application claims priority from Korean Patent Application No. 10-2024-0075428, filed on Jun. 11, 2024 in the Korean Intellectual Property Office and all the benefits accruing therefrom under 35 U.S.C. 119, the contents of which in its entirety are herein incorporated by reference.

### BACKGROUND

### 1. Technical Field

Inventive concepts relate to a semiconductor device. More specifically, the inventive concepts relates to a semiconductor device including an SRAM (Static Random-Access Memory) element.

### 2. Description of the Related Art

Semiconductor devices are in the spotlight as important elements in the electronics industry due to characteristics such as miniaturization, multi-functionality, and/or low fabricating cost. Semiconductor devices may be classified as a semiconductor memory device that stores logical data, a semiconductor logic device that performs arithmetic processing the logical data, and/or a hybrid semiconductor device including the memory element and the logic element.

As the electronic industry develops to a higher level, the demands for the characteristics of the semiconductor devices are increasing. For example, the demands for higher reliability, higher speed, and/or multi-functionality of the semiconductor devices are gradually increasing. The structures inside the semiconductor device may be becoming increasingly complex and increasingly integrated.

### SUMMARY

Aspects of inventive concepts provide a semiconductor memory device having improved performance.

However, aspects of inventive concepts are not restricted to the one set forth herein. The above and other aspects of inventive concepts will become more apparent to one of ordinary skill in the art to which inventive concepts pertains by referencing the detailed description of inventive concepts given below.

According to an embodiment of inventive concepts, a semiconductor device may include a substrate; a first power supply line and a second power supply line on the substrate and configured to have different voltages applied thereto; a word line extending in a first direction on the substrate; a bit line and a complementary bit line extending in a second direction on the substrate, the second direction intersecting the first direction; and a first cell and a second cell are arranged along the second direction on the substrate. The first cell may include a latch circuit, a first pass transistor, and a second pass transistor. The latch circuit may include a first inverter and a second inverter connected in parallel between the first power supply line and the second power supply line. The first pass transistor may connect an output node of the first inverter to the bit line, and the second pass transistor may connect an output node of the second inverter to the complementary bit line. The word line may connected to a gate of the first pass transistor and a gate of the second pass transistor. The second cell may include a first buffer transistor and a second buffer transistor. The first buffer transistor may connect the second power supply line and the bit line. The second buffer transistor may connect the second power supply line to the complementary bit line. The bit line may be connected to a gate of the first buffer transistor, and the complementary bit line may be connected to a gate of the second buffer transistor.

According to an embodiment of inventive concepts, a semiconductor device may include a cell array region including a plurality of SRAM unit cells, the plurality of SRAM unit cells arranged in a matrix form along a first direction and a second direction that intersect each other; a word line commonly connected to one row of SRAM unit cells in the first direction among the plurality of SRAM unit cells; a bit line commonly connected to one column of SRAM unit cells in the second direction among the plurality of SRAM unit cells; a complementary bit line commonly connected to the one column of SRAM unit cells; and a buffer cell region arranged along the cell array region. The buffer cell region may include a p-type first buffer transistor that connects the bit line to a ground node, and a p-type second buffer transistor that connects the complementary bit line to the ground node. The bit line may be connected to a gate of the p-type first buffer transistor, and the complementary bit line may be connected to a gate of the p-type second buffer transistor.

According to an embodiment of inventive concepts, a semiconductor device may include a first cell and a second cell arranged along a first direction. The semiconductor device may include a substrate including a first side and a second side opposite each other; a first active pattern, a second active pattern, a third active pattern, and a fourth active pattern, which are sequentially arranged in the first direction on a first side of the first cell, each of the first active pattern, the second active pattern, the third active pattern, and the fourth active pattern extending in a second direction, the second direction intersecting the first direction; a first gate structure extending in the first direction and intersecting the first active pattern; a second gate structure extending in the first direction and intersecting the third active pattern and the fourth active patterns; a third gate structure extending in the first direction and intersecting the first active pattern and the second active pattern; a fourth gate structure extending in the first direction and intersecting the fourth active pattern; a first source/drain contact connected to the first active pattern on a side face of the first gate structure; a second source/drain contact connecting the first active pattern and the second active pattern to each other, the first gate structure being between the second source/drain contact and the first source/drain contact; a first shared contact connecting the second gate structure and the second source/drain contact to each other; a third source/drain contact connected to the fourth active pattern on a side face of the fourth gate structure; a fourth source/drain contact connecting the third active pattern and the fourth active pattern to each other, the fourth gate structure being between the fourth source/drain contact and the third source/drain contact; a second shared contact connecting the third gate structure and the fourth source/drain contact to each other; a fifth active pattern extending in the second direction on a first side of the second cell; a fifth gate structure extending in the first direction and intersecting the fifth active pattern; a fifth source/drain contact connected to the fifth active pattern and on a side face of the fifth gate structure; a third shared contact connecting the fifth gate structure and the fifth source/drain contact; and a first front wiring pattern extending in the second direction on the first side of the substrate, the first front wiring pattern being connected to the first source/drain contact and the third shared contact.

### BRIEF DESCRIPTION OF THE DRAWINGS

The above and other aspects and features of inventive concepts will become more apparent by describing in detail example embodiments thereof with reference to the attached drawings, in which:

FIG. 1 is an example block diagram for explaining a semiconductor device according to some embodiments.

FIG. 2 is a circuit diagram for explaining a unit memory cell and a unit buffer cell of the semiconductor device according to some embodiments.

FIG. 3 is an example layout diagram for explaining a unit memory cell of the semiconductor device according to some embodiments.

FIG. 4 is a schematic cross-sectional view taken along A-A of FIG. 3.

FIG. 5 is a schematic cross-sectional view taken along B-B of FIG. 3.

FIG. 6 is a schematic cross-sectional view taken along C-C of FIG. 3.

FIG. 7 is a schematic cross-sectional view taken along D-D of FIG. 3.

FIG. 8 is an example layout diagram for explaining a unit buffer cell of the semiconductor device according to some embodiments.

FIG. 9 is a schematic cross-sectional view taken along E-E of FIG. 8.

FIG. 10 is a schematic cross-sectional view taken along F-F of FIG. 8.

FIG. 11 is a schematic cross-sectional view taken along G-G of FIG. 8.

FIG. 12 is a schematic cross-sectional view taken along H-H of FIG. 8.

FIG. 13 is a circuit diagram for explaining a read operation of the semiconductor device according to some embodiments.

FIG. 14 is a circuit diagram for explaining a write operation of the semiconductor device according to some embodiments.

FIG. 15 is an example layout diagram for explaining a unit buffer cell of a semiconductor device according to some embodiments.

FIG. 16 is a schematic cross-sectional view taken along I-I of FIG. 15.

FIG. 17 is an example layout diagram for explaining a unit buffer cell of a semiconductor device according to some embodiments.

FIG. 18 is a schematic cross-sectional view taken along J-J of FIG. 17.

FIG. 19 is an example layout diagram for explaining a unit memory cell of the semiconductor device according to some embodiments.

FIG. 20 is an example layout diagram for explaining the unit buffer cell of the semiconductor device according to some embodiments.

FIG. 21 is an example block diagram for explaining a semiconductor device according to some embodiments.

FIG. 22 is a circuit diagram for explaining a semiconductor device according to some embodiments.

FIG. 23 is an example layout for explaining the semiconductor device of FIG. 22.

### DETAILED DESCRIPTION

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within inventive concepts.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

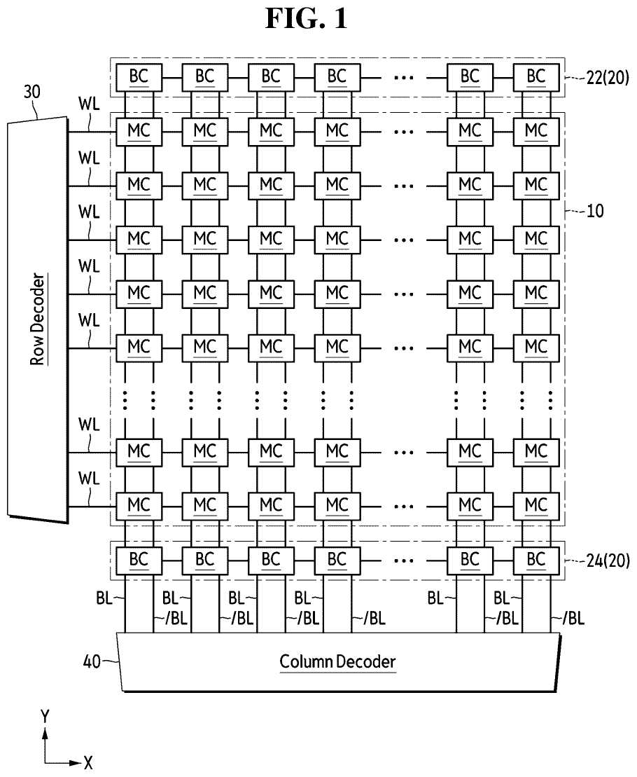

Hereinafter, a semiconductor device according to example embodiments will be described with reference to FIGS. 1 to 18.

FIG. 1 is an example block diagram for explaining a semiconductor device according to some embodiments.

Referring to FIG. 1, the semiconductor device according to some embodiments includes a cell array region 10, a buffer cell region 20, a row decoder 30, and a column decoder 40.

The cell array region 10 may include a plurality of memory cells MC arranged two-dimensionally. For example, the plurality of memory cells MC may be arranged in a matrix form along a first direction X and a second direction Y that intersect each other. In this specification, each memory cell MC may also be referred to as a “first cell”.

The cell array region 10 may be connected to the row decoder 30 through a plurality of word lines WL. The plurality of word lines WL may be spaced apart from each other, and extend in parallel in a first direction X. The word line WL extends in the first direction X, and may be commonly connected to one row of memory cells MC arranged along the first direction X among the plurality of memory cells MC.

The cell array region 10 may be connected to the column decoder 40 through a plurality of bit lines BL and a plurality of complementary bit lines/BL. The plurality of bit lines BL and the plurality of complementary bit lines/BL may be spaced apart from each other, and extend in parallel in a second direction Y. One bit line BL and one complementary bit line /BL adjacent to each other may form a pair. The pair of the bit line BL and the complementary bit line /BL may extend in the second direction Y, and be commonly connected to one column of memory cells MC arranged along the second direction Y among the plurality of memory cells MC.

The row decoder 30 may select at least one of the plurality of word lines WL. Furthermore, the row decoder 30 may transfer a voltage for performing a memory operation to the selected word line WL. The row decoder 30 may include, for example, but not limited to, a word line decoder and/or a word line driver.

The column decoder 40 may select at least a pair of bit line BL and complementary bit line /BL. Furthermore, the column decoder 40 may transfer a voltage for performing a memory operation to the selected pair of the bit line BL and the complementary bit line /BL. The column decoder 40 may include, for example, but not limited to, a bit line multiplexer and/or a sense amplifier.

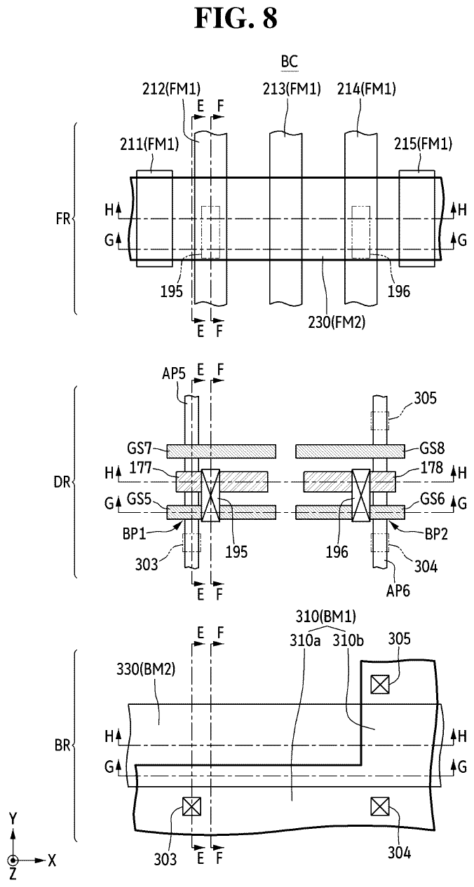

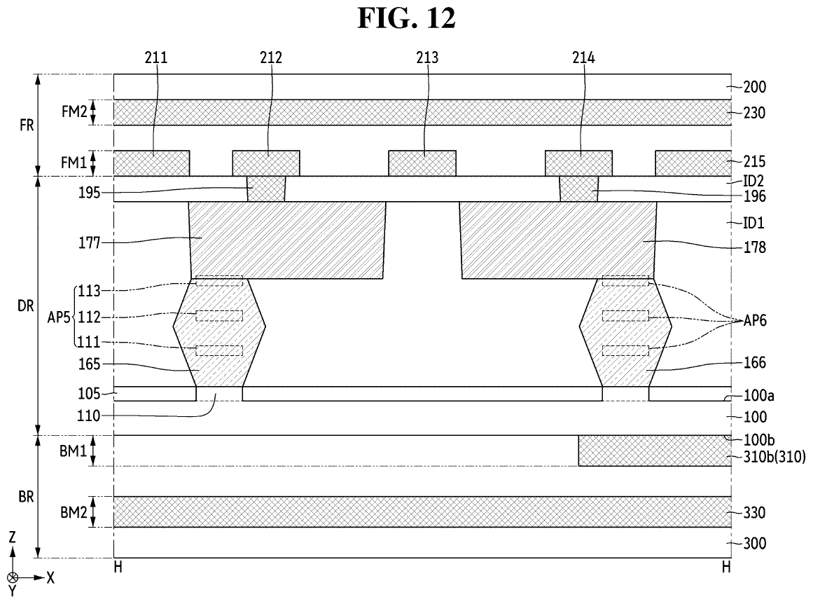

The buffer cell region 20 may be arranged along the second direction Y together with the cell array region 10. The buffer cell region 20 may include a plurality of buffer cells BC. The buffer cells BC may be arranged along the second direction Y together with the one column of the memory cells MC. A pair of the bit line BL and the complementary bit line /BL extends in the second direction Y, and may be commonly connected to the one column of the memory cells MC and the buffer cells BC. The buffer cell BC will be described below in detail in the description of FIGS. 8 and 12. In this specification, each buffer cell BC may also be referred to as a “second cell”.

In some embodiments, the buffer cell region 20 may be disposed on at least one side of the cell array region 10 in the second direction Y. For example, the buffer cell region 20 may include a first buffer cell region 22 and a second buffer cell region 24, which are each disposed on both sides of the cell array region 10 in the second direction Y. The cell array region 10 may be interposed between the first buffer cell region 22 and the column decoder 40 in the second direction Y. The second buffer cell region 24 may be interposed between the cell array region 10 and the column decoder 40 in the second direction Y. The first buffer cell region 22 and the second buffer cell region 24 may each include a plurality of buffer cells BC arranged along the first direction X.

In some embodiments, one of the first buffer cell region 22 and the second buffer cell region 24 may be omitted.

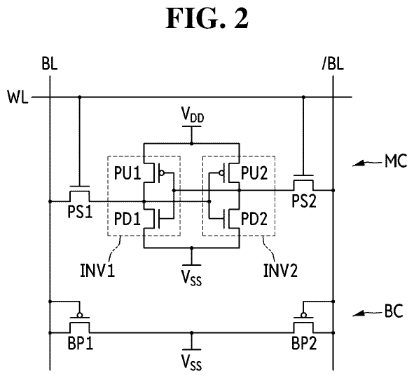

FIG. 2 is a circuit diagram for explaining a unit memory cell and a unit buffer cell of the semiconductor device according to some embodiments.

Referring to FIG. 2, the semiconductor device according to some embodiments includes a memory cell MC and a buffer cell BC commonly connected to the pair of the bit line BL and the complementary bit line /BL.

The memory cell MC may be a static random-access memory (SRAM) unit cell. For example, the memory cell MC may include a pair of inverters INV1 and INV2 connected in parallel between a power supply node V_{DD} and a ground node V_{SS}, and a first pass transistor PS1 and a second pass transistor PS2 connected to output nodes of each of the inverters INV1 and INV2.

In order to configure a single latch circuit, an input node of the first inverter INV1 may be connected to the output node of the second inverter INV2, and an input node of the second inverter INV2 may be connected to the output node of the first inverter INV1.

The first inverter INV1 may include a first pull-up transistor PU1 and a first pull-down transistor PD1 connected in series, and the second inverter INV2 may include a second pull-up transistor PU2 and a second pull-down transistor PD2 connected in series. The first pull-up transistor PU1 and the second pull-up transistor PU2 may each be a P-type (e.g., PFET (P-type Field Effect Transistor)), and the first pull-down transistor PD1 and the second pull-down transistor PD2 may each be an N-type (e.g., NFET (N-type Field Effect Transistor)).

The first pass transistor PS1 may connect the bit line BL and the output node of the first inverter INV1. The second pass transistor PS2 may connect the complementary bit line /BL and the output node of the second inverter INV2. The gate of the first pass transistor PS1 and the gate of the second pass transistor PS2 may be connected to the word line WL.

The buffer cell BC may include a first buffer transistor BP1 and a second buffer transistor BP2.

The first buffer transistor BP1 may connect the bit line BL and the ground node V_{SS}. A gate of the first buffer transistor BP1 may be connected to the bit line BL. The first buffer transistor BP1 may be a PFET. The bit line BL may be commonly connected to the source and gate of the first buffer transistor BP1.

The second buffer transistor BP2 may connect the complementary bit line /BL and the ground node VSS. The gate of the second buffer transistor BP2 may be connected to the complementary bit line /BL. The second buffer transistor BP2 may be a PFET. The complementary bit line /BL may be commonly connected to the source and gate of the second buffer transistor BP2.

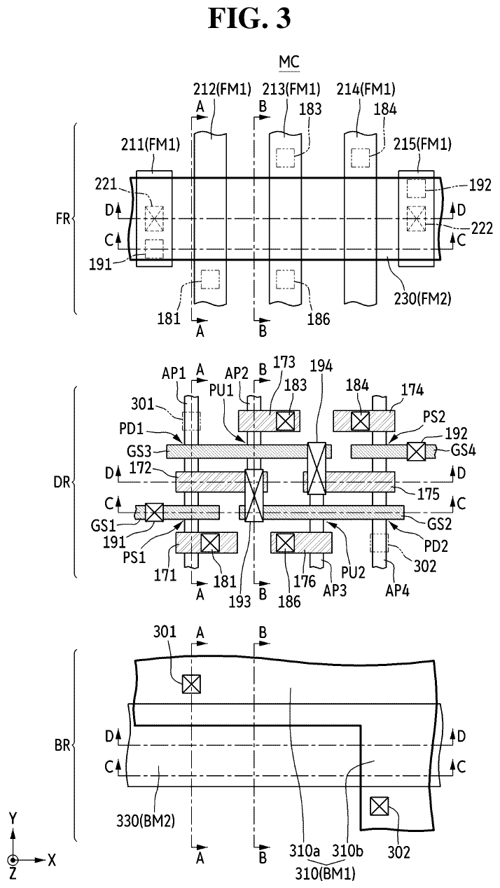

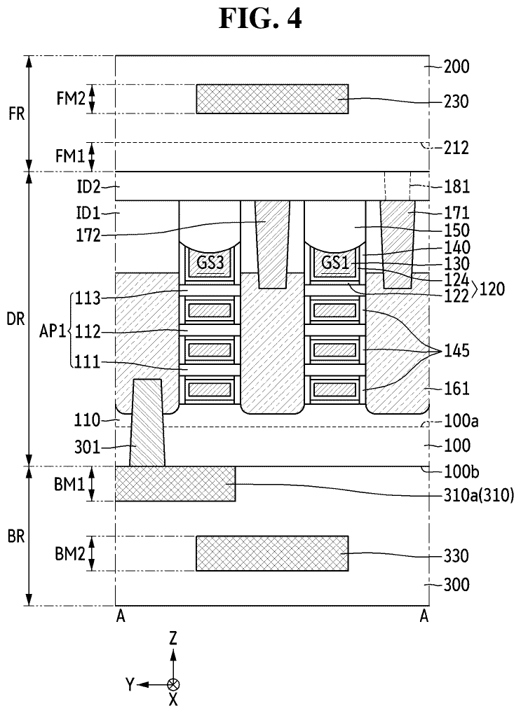

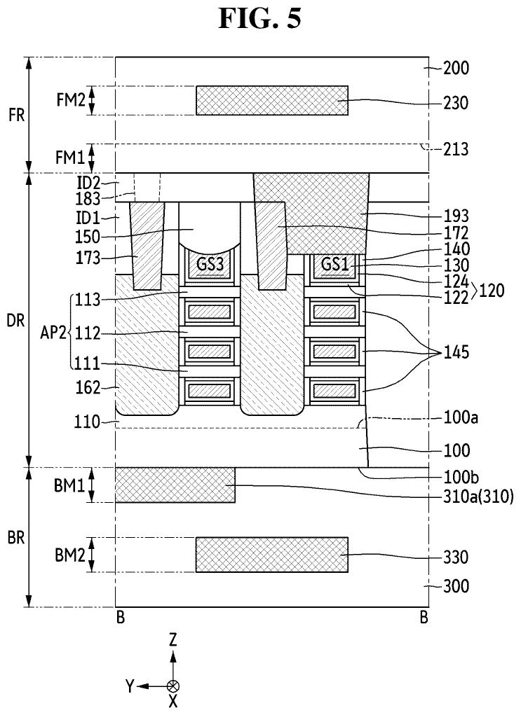

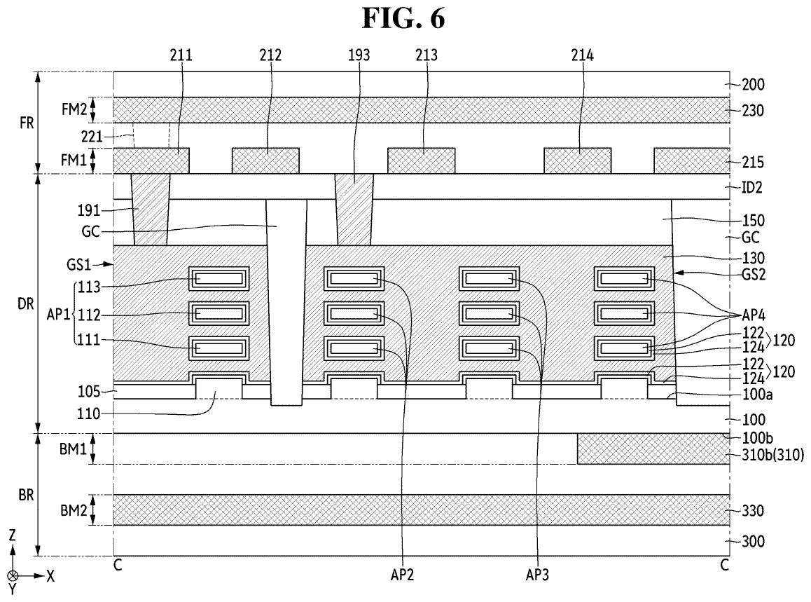

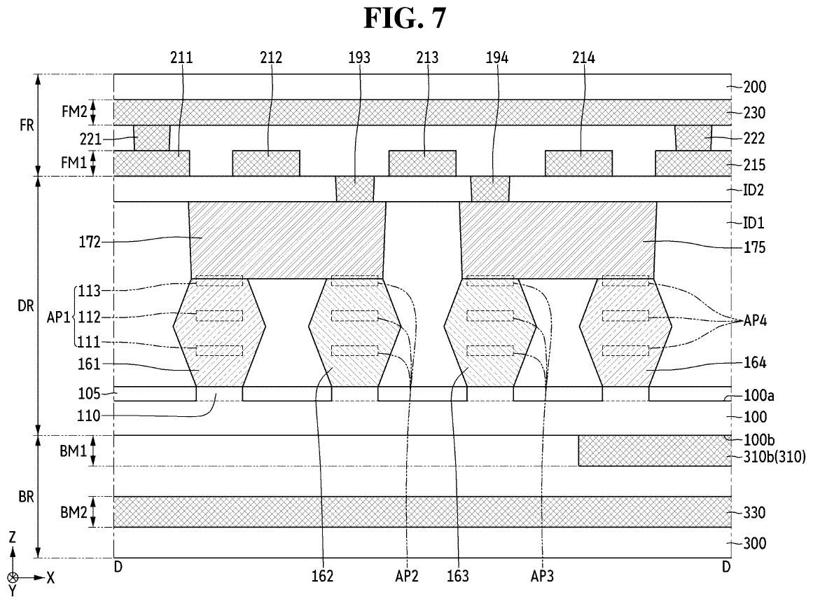

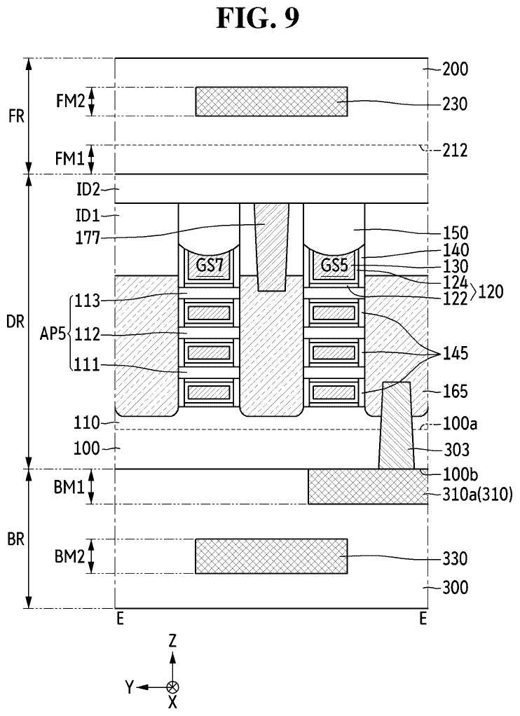

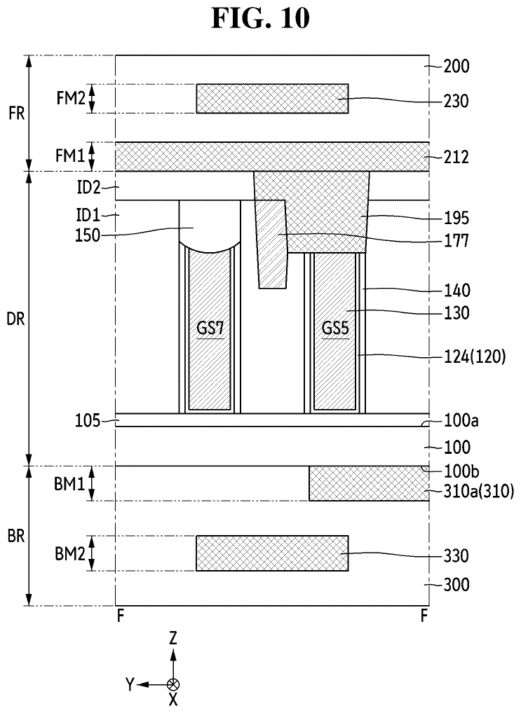

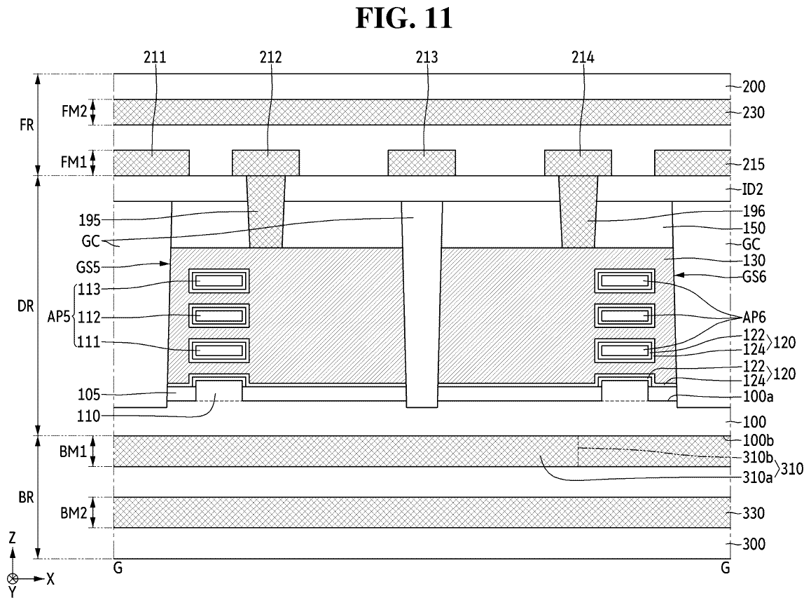

FIG. 3 is an example layout diagram for explaining a unit memory cell of the semiconductor device according to some embodiments. FIG. 4 is a schematic cross-sectional view taken along A-A of FIG. 3. FIG. 5 is a schematic cross-sectional view taken along B-B of FIG. 3. FIG. 6 is a schematic cross-sectional view taken along C-C of FIG. 3. FIG. 7 is a schematic cross-sectional view taken along D-D of FIG. 3. FIG. 8 is an example layout diagram for explaining a unit buffer cell of the semiconductor device according to some embodiments. FIG. 9 is a schematic cross-sectional view taken along E-E of FIG. 8. FIG. 10 is a schematic cross-sectional view taken along F-F of FIG. 8. FIG. 11 is a schematic cross-sectional view taken along G-G of FIG. 8. FIG. 12 is a schematic cross-sectional view taken along H-H of FIG. 8.

Referring to FIGS. 1 to 12, the semiconductor device according to some embodiments includes an element region DR, a front region FR, and a back region BR.

The element region DR may include a substrate 100, a field insulating film 105, first to sixth active patterns AP1 to AP6, first to eighth gate structures GS1 to GS8, first to eighth source/drain contacts 171 to 178, a first interlayer insulating film ID1, and a second interlayer insulating film ID2.

The substrate 100 may be bulk silicon or silicon-on-insulator (SOI). In contrast, the substrate 100 may be a silicon substrate, or may include other materials, for example, silicon germanium, silicon germanium-on-insulator (SGOI), indium antimonide, lead telluride, indium arsenide, indium phosphide, gallium arsenide or gallium antimonide. Alternatively, the substrate 100 may be an epi-layer formed on a base substrate.

In some embodiments, the substrate 100 may be an insulating substrate including an insulating material. For example, the substrate 100 may include, but not limited to, at least one of silicon oxide, silicon oxynitride, silicon oxycarbonitride, and combinations thereof. As an example, the substrate 100 may include a silicon oxide film.

The substrate 100 may include a first side 100a and a second side 100b that are opposite to each other. In the following embodiments, the first side 100a may also be referred to as a front side of the substrate 100, and the second side 100b may also be referred to as a back side of the substrate 100.

The first to fourth active patterns AP1 to AP4 may be formed on the first side 100a of the memory cell MC. The first to fourth active patterns AP1 to AP4 may be arranged in sequence along the first direction X. The first to fourth active patterns AP1 to AP4 may be spaced apart from each other in the first direction X, and each may extend long in the second direction Y.

The fifth and sixth active patterns AP5 and AP6 may be formed on the first side 100a of the buffer cell BC. The fifth and sixth active patterns AP5 and AP6 may be arranged in sequence along the first direction X. The fifth and sixth active patterns AP5 and AP6 may be spaced apart from each other in the first direction X, and each may extend long in the second direction Y. In some embodiments, the fifth active pattern AP5 may be arranged along the second direction Y together with the first active pattern AP1. In some embodiments, the sixth active pattern AP6 may be arranged along the second direction Y together with the fourth active pattern AP4.

The first to sixth active patterns AP1 to AP6 may each include silicon (Si) or germanium (Ge) which is an element semiconductor material. Alternatively, the first to sixth active patterns AP1 to AP6 may each include a compound semiconductor, for example, a group IV-IV compound semiconductor or a group III-V compound semiconductor. The group IV-IV compound semiconductor may be, for example, a binary compound or a ternary compound which includes at least two of carbon (C), silicon (Si), germanium (Ge), and tin (Sn) or a compound obtained by doping the elements with a group IV element. The group III-V compound semiconductor may be, for example, one of a binary compound, a ternary compound or a quaternary compound formed by combining at least one of aluminum (Al), gallium (Ga), and indium (In) as a group III element with at least one of phosphorus (P), arsenic (As), and antimony (Sb) as a group V element.

In some embodiments, the first active pattern AP1 and the fourth active pattern AP4 may each be used as a channel region of an NFET. In some embodiments, the second active pattern AP2, the third active pattern AP3, the fifth active pattern AP5, and the sixth active pattern AP6 may each be used as a channel region of a PFET.

In some embodiments, each of the first to sixth active patterns AP1 to AP6 may include a plurality of bridge patterns (e.g., the first to third bridge patterns 111 to 113) that are sequentially stacked on the substrate 100 and spaced apart from each other. Such first to sixth active patterns AP1 to AP6 may be used as a channel region of an MBCFET® that includes a multi-bridge channel. The number of bridge patterns included in each of the first to sixth active patterns AP1 to AP6 is merely an example and is not limited to the number shown.

In some embodiments, a fin-type pattern 110 may be formed between the substrate 100 and the first bridge pattern 111. The fin-type pattern 110 may protrude from the first side 100a of the substrate 100 and extend in the second direction Y. In some embodiments, the fin-type pattern 110 may be an insulating pattern including an insulating material.

The field insulating film 105 may be formed on the substrate 100.

In some embodiments, the field insulating film 105 may cover at least a part of the side of the fin-type pattern 110. The field insulating film 105 may include, for example, but not limited to, at least one of silicon oxide, silicon nitride, silicon oxynitride, and combinations thereof.

The first to fourth gate structures GS1 to GS4 may be formed on the substrate 100 and the field insulating film 105 of the memory cell MC. The fifth to sixth gate structures GS5 to GS6 may be formed on the substrate 100 and the field insulating film 105 of the buffer cell BC. The first to eighth gate structures GS1 to GS8 may each extend long in the first direction X.

A first gate structure GS1 may intersect the first active pattern AP1. For example, the bridge patterns 111 to 113 of the first active pattern AP1 may each extend in the second direction Y and penetrate the first gate structure GS1. The first gate structure GS1 may be provided as a gate of the first pass transistor PS1. For example, the first active pattern AP1 intersecting the first gate structure GS1 may be provided as a channel region of the first pass transistor PS1.

A second gate structure GS2 may be spaced apart from the first gate structure GS1 in the first direction X. The second gate structure GS2 may intersect the third active pattern AP3 and the fourth active pattern AP4. For example, the bridge patterns 111 to 113 of the third active pattern AP3 and the bridge patterns 111 to 113 of the fourth active pattern AP4 may extend in the second direction Y, and penetrate the second gate structure GS2. The second gate structure GS2 may be provided as a gate of the second inverter INV2. For example, the third active pattern AP3 intersecting the second gate structure GS2 may be provided as a channel region of the second pull-up transistor PU2, and the fourth active pattern AP4 intersecting the second gate structure GS2 may be provided as a channel region of the second pull-down transistor PD2.

A third gate structure GS3 may be spaced apart from the first gate structure GS1 and the second gate structure GS2 in the second direction Y. The third gate structure GS3 may intersect the first active pattern AP1 and the second active pattern AP2. For example, the bridge patterns 111 to 113 of the first active pattern AP1 and the bridge patterns 111 to 113 of the second active pattern AP2 may extend in the second direction Y and penetrate the third gate structure GS3. The third gate structure GS3 may be provided as a gate of the first inverter INV1. For example, the first active pattern AP1 that intersects the third gate structure GS3 may be provided as a channel region of the first pull-down transistor PD1, and the second active pattern AP2 that intersects the third gate structure GS3 may be provided as a channel region of the first pull-up transistor PU1.

A fourth gate structure GS4 may be spaced apart from the third gate structure GS3 in the first direction X. The fourth gate structure GS4 may intersect the fourth active pattern AP4. For example, the bridge patterns 111 to 113 of the fourth active pattern AP4 may extend in the second direction Y and penetrate the fourth gate structure GS4. The fourth gate structure GS4 may be provided as a gate of the second pass transistor PS2. For example, the fourth active pattern AP4 that intersects the fourth gate structure GS4 may be provided as a channel region of the second pass transistor PS2.

A fifth gate structure GS5 may intersect the fifth active pattern AP5. For example, the bridge patterns 111 to 113 of the fifth active pattern AP5 each extend in the second direction Y and penetrate the fifth gate structure GS5. The fifth gate structure GS5 may be provided as a gate of the first buffer transistor BP1. For example, the fifth active pattern AP5 that intersects the fifth gate structure GS5 may be provided as a channel region of the first buffer transistor BP1.

A sixth gate structure GS6 may intersect the sixth active pattern AP6. For example, the bridge patterns 111 to 113 of the sixth active pattern AP6 may each extend in the second direction Y and penetrate the sixth gate structure GS6. The sixth gate structure GS6 may be provided as a gate of the second buffer transistor BP2. For example, the sixth active pattern AP6 that intersects the sixth gate structure GS6 may be provided as a channel region of the second buffer transistor BP2.

A seventh gate structure GS7 may be spaced apart from the fifth gate structure GS5 in the second direction Y. The seventh gate structure GS7 may intersect the fifth active pattern AP5. For example, the bridge patterns 111 to 113 of the fifth active pattern AP5 may each extend in the second direction Y and penetrate the seventh gate structure GS7. In some embodiments, the seventh gate structure GS7 may be interposed between the memory cell MC and the fifth gate structure GS5.

An eighth gate structure GS8 may be spaced apart from the sixth gate structure GS6 in the second direction Y. The eighth gate structure GS8 may intersect the sixth active pattern AP6. For example, the bridge patterns 111 to 113 of the sixth active pattern AP6 may each extend in the second direction Y and penetrate the eighth gate structure GS8. In some embodiments, the eighth gate structure GS8 may be interposed between the memory cell MC and the sixth gate structure GS6.

In some embodiments, each of the first to eighth gate structures GS1 to GS8 may be separated by a separation pattern GC. For example, the separation pattern GC may extend in the second direction Y between the first active pattern AP1 and the second active pattern AP2, and separate the first gate structure GS1 and the second gate structure GS2. Also, for example, the separation pattern GC may extend in the second direction Y between the third active pattern AP3 and the fourth active pattern AP4, and separate the third gate structure GS3 and the fourth gate structure GS4. Also, for example, the separation pattern GC may extend in the second direction Y between the fifth active pattern AP5 and the sixth active pattern AP6, may separate the fifth gate structure GS5 and the sixth gate structure GS6, and may separate the seventh gate structure GS7 and the eighth gate structure GS8.

The separation pattern GC may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof.

In some embodiments, each of the first to eighth gate structures GS1 to GS8 may include a gate dielectric film 120, a gate electrode 130, a gate spacer 140, and a gate capping film 150.

The gate dielectric film 120 may be interposed between each of the first to sixth active patterns AP1 to AP6 and the gate electrode 130. The gate dielectric film 120 may include at least one of a dielectric material, for example, silicon oxide, silicon oxynitride, silicon nitride or a high dielectric constant material having a higher dielectric constant than silicon oxide.

The gate electrode 130 may extend long in the first direction X and intersect the first to sixth active patterns AP1 to AP6. The bridge patterns 111 to 113 of the first to sixth active patterns AP1 to AP6 may each extend in the second direction Y and penetrate the gate electrode 130. The gate electrode 130 may include at least one of a conductive material, for example, but not limited to, TiN, WN, TaN, Ru, TiC, TaC, Ti, Ag, Al, TiAl, TiAlN, TiAlC, TaCN, TaSiN, Mn, Zr, W, Al, and combinations thereof. The gate electrode 130 may be formed by, but not limited to, a replacement process.

Although the gate electrode 130 is only shown as being a single film, this is an example only, and the gate electrode 130 may, of course, be a multiple film formed by stacking the plurality of conductive films. For example, the gate electrode 130 may include a work function adjusting film that adjusts a work function, and a filling conductive film that fills a space formed by the work function adjusting film. The work function adjusting film may include, for example, but not limited to, at least one of TiN, TaN, TiC, TaC, TiAlC, and combinations thereof. The filling conductive film may include, for example, but not limited to, W or Al.

The gate spacer 140 may extend along the side face of the gate electrode 130. The bridge patterns 111 to 113 of the first to sixth active patterns AP1 to AP6 may each extend in the second direction Y and penetrate the gate spacer 140. The gate spacer 140 may include at least one of insulating materials, for example, but not limited to, at least one of silicon oxide, silicon nitride, silicon oxynitride, silicon oxycarbide, silicon boron nitride, silicon boron carbonitride, silicon oxycarbonitride, and combinations thereof.

In some embodiments, the gate dielectric film 120 may include an interfacial film 122 and a high dielectric film 124 that are sequentially stacked on the first to sixth active patterns AP1 to AP6.

The interfacial film 122 may surround the periphery of each of the bridge patterns 111 to 113. For example, the interfacial film 122 may extend conformally along the periphery of each of the bridge patterns 111 to 113. In some embodiments, the interfacial film 122 may include an oxide film formed by oxidizing the surfaces of each of the bridge patterns 111 to 113. As an example, when each of the bridge patterns 111 to 113 includes silicon (Si), the interfacial film 122 may include a silicon oxide film.

The high dielectric film 124 may surround the periphery of the interfacial film 122. Also, a part of the high dielectric film 124 may be interposed between the gate electrode 130 and the gate spacer 140. For example, the high dielectric film 124 may conformally extend along the periphery of the interfacial film 122 and the profile of the inner face of the gate spacer 140. The high dielectric film 124 may also extend further along the upper face of the field insulating film 105.

In some embodiments, the high dielectric film 124 may include a high dielectric constant material having a dielectric constant greater than that of silicon oxide. The high dielectric constant material may include, for example, but not limited to, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), and combinations thereof.

The gate capping film 150 may extend along the upper face of the gate electrode 130. The gate capping film 150 may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof.

The first to sixth source/drain regions 161 to 166 may be formed inside the first to sixth active patterns AP1 to AP6, respectively. In this specification, the first to sixth source/drain regions 161 to 166 may be explained as components included in the first to sixth active patterns AP1 to AP6, and may be explained as separate components different from the first to sixth active patterns AP1 to AP6.

For example, the first active pattern AP1 may include a first source/drain region 161. The first source/drain region 161 may be formed in the first active pattern AP1 on a side face of the first gate structure GS1 and a side face of the third gate structure GS3.

For example, the second active pattern AP2 may include a second source/drain region 162. The second source/drain region 162 may be formed inside the second active pattern AP2 on a side face of the second gate structure GS2 and a side face of the third gate structure GS3.

For example, the third active pattern AP3 may include a third source/drain region 163. The third source/drain region 163 may be formed inside the second active pattern AP2 on the side face of the second gate structure GS2 and the side face of the third gate structure GS3.

For example, the fourth active pattern AP4 may include a fourth source/drain region 164. The fourth source/drain region 164 may be formed inside the fourth active pattern AP4 on the side face of the second gate structure GS2 and a side face of the fourth gate structure GS4.

For example, the fifth active pattern AP5 may include a fifth source/drain region 165. The fifth source/drain region 165 may be formed inside the fifth active pattern AP5 on a side face of the fifth gate structure GS5 and a side face of the seventh gate structure GS7.

For example, the sixth active pattern AP6 may include a sixth source/drain region 166. The sixth source/drain region 166 may be formed inside the sixth active pattern AP6 on the side face of the sixth gate structure GS6 and a side face of the eighth gate structure GS8.

Each of the bridge patterns 111 to 113 of the first to sixth active patterns AP1 to AP6 may penetrate the gate electrode 130 and the gate spacer 140, and be connected to the first to sixth source/drain regions 161 to 166. The first to sixth source/drain regions 161 to 166 may be separated from the gate electrode 130 by the gate spacer 140.

In some embodiments, each of the first to sixth source/drain regions 161 to 166 may include an epitaxial layer doped with impurities. For example, the first to sixth source/drain regions 161 to 166 may include epitaxial patterns that are grown from the first to sixth active patterns AP1 to AP6 by an epitaxial growth method.

When each of the first active pattern AP1 and the fourth active pattern AP4 is a channel region of an NFET, each of the first source/drain region 161 and the fourth source/drain region 164 may include N-type impurities (e.g., P, Sb, or As) or impurities for limiting and/or preventing diffusion of N-type impurities.

When each of the second active pattern AP2, the third active pattern AP3, the fifth active pattern AP5, and the sixth active pattern AP6 is a channel region of a PFET, each of the second source/drain region 162, the third source/drain region 163, the fifth source/drain region 165, and the sixth source/drain region 166 may include P-type impurities (e.g., B, In, Ga, or Al) or impurities for limiting and/or preventing diffusion of P-type impurities.

In some embodiments, each of the first to eighth gate structures GS1 to GS8 may further include an internal spacer 145. The internal spacer 145 may be formed on a side face of the gate electrode 130 between the bridge patterns 111 to 113. The first to sixth source/drain regions 161 to 166 may be separated from the gate electrode 130 by the gate dielectric film 120, the gate spacer 140, and/or the internal spacer 145. In some embodiments, the internal spacer 145 may be omitted.

The first to eighth source/drain contacts 171 to 178 may be electrically connected to the first to sixth active patterns AP1 to AP6. The shape, placement, and the like of the first to eighth source/drain contacts 171 to 178 are merely an example and are not limited to those shown in the drawings.

A first source/drain contact 171 may be connected to the first active pattern AP1. For example, the first source/drain contact 171 may come into contact with the first source/drain region 161 on one side of the first gate structure GS1. The first gate structure GS1 may be interposed between the first source/drain contact 171 and the second source/drain contact 172.

A second source/drain contact 172 may connect the first active pattern AP1 and the second active pattern AP2. For example, the second source/drain contact 172 may extend in the first direction X and come into contact with both the first source/drain region 161 and the second source/drain region 162. The second source/drain contact 172 may be interposed between the first gate structure GS1 and the third gate structure GS3, and between the second gate structure GS2 and the third gate structure GS3.

A third source/drain contact 173 may be connected to the second active pattern AP2. For example, the third source/drain contact 173 may come into contact with the second source/drain region 162 on one side of the third gate structure GS3. A third gate structure GS3 may be interposed between the second source/drain contact 172 and the third source/drain contact 173.

A fourth source/drain contact 174 may be connected to the fourth active pattern AP4. For example, the fourth source/drain contact 174 may come into contact with the fourth source/drain region 164 on one side of the fourth gate structure GS4. The fourth gate structure GS4 may be interposed between the fourth source/drain contact 174 and a fifth source/drain contact 175.

A fifth source/drain contact 175 may connect the third active pattern AP3 and the fourth active pattern AP4. For example, the fifth source/drain contact 175 may extend in the first direction X and come into contact with both the third source/drain region 163 and the fourth source/drain region 164. The fifth source/drain contact 175 may be interposed between the second gate structure GS2 and the third gate structure GS3, and between the second gate structure GS2 and the fourth gate structure GS4.

A sixth source/drain contact 176 may be connected to the third active pattern AP3. For example, the sixth source/drain contact 176 may come into contact with the third source/drain region 163 on one side of the second gate structure GS2. The second gate structure GS2 may be interposed between the fifth source/drain contact 175 and the sixth source/drain contact 176.

The second source/drain contact 172 may be electrically connected to the second gate structure GS2. For example, a first shared contact 193 may be formed on the second gate structure GS2 and the second source/drain contact 172. The first shared contact 193 may extend in the second direction Y, and connect the gate electrode 130 of the second gate structure GS2 to the second source/drain contact 172. An output node of the first inverter INV1 (e.g., the second source/drain contact 172) may be connected to an input node of the second inverter INV2 (e.g., the second gate structure GS2) through the first shared contact 193.

The fifth source/drain contact 175 may be electrically connected to the third gate structure GS3. For example, a second shared contact 194 may be formed on the third gate structure GS3 and the fifth source/drain contact 175. The second shared contact 194 may extend in the second direction Y and connect the gate electrode 130 of the third gate structure GS3 and the fifth source/drain contact 175. An output node of the second inverter INV2 (e.g., the fifth source/drain contact 175) may be connected to an input node of the first inverter INV1 (e.g., the third gate structure GS3) through the second shared contact 194.

A seventh source/drain contact 177 may be connected to the fifth active pattern AP5. For example, the seventh source/drain contact 177 may come into contact with the fifth source/drain region 165 between the fifth gate structure GS5 and the seventh gate structure GS7.

The seventh source/drain contact 177 may be electrically connected to the fifth gate structure GS5. For example, a third shared contact 195 may be formed on the fifth gate structure GS5 and the seventh source/drain contact 177. The third shared contact 195 may extend in the second direction Y, and connect the gate electrode 130 of the fifth gate structure GS5 and the seventh source/drain contact 177. The source and gate of the first buffer transistor BP1 may have the same potential through the third shared contact 195.

An eighth source/drain contact 178 may be connected to the sixth active pattern AP6. For example, the eighth source/drain contact 178 may come into contact with the sixth source/drain region 166 between the sixth gate structure GS6 and the eighth gate structure GS8.

The eighth source/drain contact 178 may be electrically connected to the sixth gate structure GS6. For example, a fourth shared contact 196 may be formed on the sixth gate structure GS6 and the eighth source/drain contact 178. The fourth shared contact 196 extends in the second direction Y, and may connect the gate electrode 130 of the sixth gate structure GS6 and the eighth source/drain contact 178. The source and gate of the second buffer transistor BP2 may have the same potential through the fourth shared contact 196.

The first interlayer insulating film ID1 may fill the space on the side faces of the first to eighth gate structures GS1 to GS8. For example, the first interlayer insulating film ID1 may cover the first to sixth source/drain regions 161 to 166. The second interlayer insulating film ID2 may cover the first to eighth gate structures GS1 to GS8 and the first interlayer insulating film ID1.

The first interlayer insulating film ID1 and the second interlayer insulating film ID2 may each include, but not limited to, at least one of silicon oxide, silicon nitride, silicon oxynitride, silicon oxycarbide, silicon boronitride, silicon boron carbonitride, silicon oxycarbonitride, and a low dielectric constant material having a dielectric constant smaller than that of silicon oxide.

The front region FR may be formed on the first side 100a of the substrate 100. The front region FR may include a first level front wiring FM1 and a second level front wiring FM2. For example, a front inter-wiring insulating film 200 may be formed on the second interlayer insulating film ID2. Each of the first level front wiring FM1 and the second level front wiring FM2 may be formed inside the front inter-wiring insulating film 200 to form an electrical path.

The first level front wiring FM1 and the second level front wiring FM2 may be sequentially stacked on the first side 100a of the substrate 100. That is, the second level front wiring FM2 may be disposed at an upper lever than the first level front wiring FM1. The expression being disposed “at the upper level” in the front region FR means being disposed away from the substrate 100 in the vertical direction (hereinafter, the third direction Z). For example, the second level front wiring FM2 may be spaced apart from the first side 100a farther than the first level front wiring FM1 in the third direction Z.

In some embodiments, the first level front wiring FM1 may include first to fifth front wiring patterns 211 to 215 on the memory cell MC and the buffer cell BC. The first to fifth front wiring patterns 211 to 215 may be arranged in sequence along the first direction X. The first to fifth front wiring patterns 211 to 215 may be arranged at the same level. In this specification, the expression being disposed at the “same level” means being disposed at the same height in the third direction Z on the basis of the substrate 100.

The first front wiring pattern 211 on the memory cell MC may be connected to the first gate structure GS1. For example, a first gate contact 191 which penetrates the second interlayer insulating film ID2 and the gate capping film 150 and comes into contact with the gate electrode 130 of the first gate structure GS1 may be formed. The first front wiring pattern 211 may be electrically connected to the gate electrode 130 of the first gate structure GS1 through the first gate contact 191.

In some embodiments, the first front wiring pattern 211 on the buffer cell BC may electrically float. In some embodiments, unlike the shown example, the first front wiring pattern 211 on the buffer cell BC may be omitted.

The second front wiring pattern 212 on the memory cell MC may be connected to the first source/drain contact 171. For example, a first contact via 181 which penetrates the second interlayer insulating film ID2 and comes into contact with the first source/drain contact 171 may be formed. The second front wiring pattern 212 may be electrically connected to the first source/drain contact 171 through the first contact via 181.

The second front wiring pattern 212 on the buffer cell BC may be connected to the fifth gate structure GS5 and the seventh source/drain contact 177. For example, the third shared contact 195 may be electrically connected to the second front wiring pattern 212.

The second front wiring pattern 212 may extend long in the second direction Y over the memory cell MC and the buffer cell BC. The second front wiring pattern 212 may be provided as the bit line BL. The second front wiring pattern 212 may be commonly connected to the first pass transistor PS1 of the memory cell MC and the first buffer transistor BP1 of the buffer cell BC.

The third front wiring pattern 213 on the memory cell MC may be connected to the third source/drain contact 173 and the sixth source/drain contact 176. For example, a second contact via 183 which penetrates the second interlayer insulating film ID2 and comes into contact with the third source/drain contact 173 may be formed, and a third contact via 186 which penetrates the second interlayer insulating film ID2 and comes into contact with the second sixth source/drain contact 176 may be formed. The third front wiring pattern 213 may be electrically connected to the third source/drain contact 173 through the second contact via 183, and may be electrically connected to the sixth source/drain contact 176 through the third contact via 186.

The third front wiring pattern 213 may be provided as a first power supply line that applies a first power supply voltage (e.g., V_{DD}) to the first pull-up transistor PU1 and the second pull-up transistor PU2.

In some embodiments, the third front wiring pattern 213 may extend long in the second direction Y over the memory cell MC and the buffer cell BC. In some embodiments, unlike the shown example, the third front wiring pattern 213 on the buffer cell BC may be omitted.

A fourth front wiring pattern 214 on the memory cell MC may be connected to the fourth source/drain contact 174. For example, a fourth contact via 184 which penetrates the second interlayer insulating film ID2 and comes into contact with the fourth source/drain contact 174 may be formed. The fourth front wiring pattern 214 may be electrically connected to the fourth source/drain contact 174 through the fourth contact via 184.

The fourth front wiring pattern 214 on the buffer cell BC may be connected to the sixth gate structure GS6 and the eighth source/drain contact 178. For example, the fourth shared contact 196 may be electrically connected to the fourth front wiring pattern 214.

The fourth front wiring pattern 214 may extend long in the second direction Y over the memory cell MC and the buffer cell BC. The fourth front wiring pattern 214 may be provided as a complementary bit line /BL. The fourth front wiring pattern 214 may be commonly connected to the second pass transistor PS2 of the memory cell MC and the second buffer transistor BP2 of the buffer cell BC.

A fifth front wiring pattern 215 on the memory cell MC may be connected to the fourth gate structure GS4. For example, a second gate contact 192 which penetrates the second interlayer insulating film ID2 and the gate capping film 150 and comes into contact with the gate electrode 130 of the fourth gate structure GS4 may be formed. The fifth front wiring pattern 215 may be electrically connected to the gate electrode 130 of the fourth gate structure GS4 through the second gate contact 192.

In some embodiments, the fifth front wiring pattern 215 on the buffer cell BC may electrically float. In some embodiments, unlike the shown example, the fifth front wiring pattern 215 on the buffer cell BC may be omitted.

In some embodiments, the second level front wiring FM2 may include a sixth front wiring pattern 230 on the memory cell MC and the buffer cell BC. The sixth front wiring pattern 230 may extend long in the first direction X.

The sixth front wiring pattern 230 on the memory cell MC may be connected to the first front wiring pattern 211 and the fifth front wiring pattern 215. For example, inside the front inter-wiring insulating film 200, a first front via pattern 221 which connects the first front wiring pattern 211 and the sixth front wiring pattern 230 may be formed, and a second front via pattern 222 which connects the wiring pattern 215 and the sixth front wiring pattern 230 may be formed.

The sixth front wiring pattern 230 may be provided as the word line WL. The sixth front wiring pattern 230 may be commonly connected to a gate (e.g., the first gate structure GS1) of the first pass transistor PS1 and a gate (e.g., the fourth gate structure GS4) of the second pass transistor PS2.

In some embodiments, the sixth front wiring pattern 230 on the buffer cell BC may electrically float. In some embodiments, unlike the shown example, the sixth front wiring pattern 230 on the buffer cell BC may be omitted.

The back region BR may be formed on the second side 100b of the substrate 100. The back region BR may include a first level back wiring BM1 and a second level back wiring BM2. For example, a back wiring inter-wiring insulating film 300 may be formed on the second side 100b of the substrate 100. Each of the first level back wiring BM1 and the second level back wiring BM2 may be formed inside the back wiring inter-wiring insulating film 300 to form an electrical path.

The first level back wiring BM1 and the second level back wiring BM2 may be sequentially stacked on the second side 100b of the substrate 100. That is, the second level back wiring BM2 may be disposed at a higher level than the first level back wiring BM1. The expression being disposed “at a higher level” in the back region BR means being disposed away from the substrate 100 in the vertical direction (hereinafter, the third direction Z). For example, the second level back wiring BM2 may be spaced apart from the second side 100b farther than the first level back wiring BM1 in the third direction Z.

In some embodiments, the first level back wiring BM1 may include a first back wiring pattern 310 on the memory cell MC and the buffer cell BC.

The first back wiring pattern 310 on the memory cell MC may be connected to the first active pattern AP1. For example, a first back source/drain contact 301 that comes into contact with the first source/drain region 161 may be formed on one side of the third gate structure GS3. The first back source/drain contact 301 penetrates the substrate 100, and may connect the first back wiring pattern 310 and the first source/drain region 161. The third gate structure GS3 may be interposed between the second source/drain contact 172 and the first back source/drain contact 301.

The first back wiring pattern 310 on the memory cell MC may be connected to the fourth active pattern AP4. For example, a second back source/drain contact 302 that comes into contact with the fourth source/drain region 164 may be formed on one side of the second gate structure GS2. The second back source/drain contact 302 may penetrate the substrate 100 and connect the first back wiring pattern 310 and the fourth source/drain region 164. The second gate structure GS2 may be interposed between the fifth source/drain contact 175 and the second back source/drain contact 302.

The first back wiring pattern 310 on the memory cell MC may be provided as a second power supply line that applies a second power supply voltage (e.g., V_{SS}) different from the first power supply voltage (e.g., V_{DD}) to the first pull-down transistor PD1 and the second pull-down transistor PD2.

The first back wiring pattern 310 on the buffer cell BC may be connected to the fifth active pattern AP5. For example, a third back source/drain contact 303 that comes into contact with the fifth source/drain region 165 may be formed on one side of the fifth gate structure GS5. The third back source/drain contact 303 may penetrate the substrate 100 and connect the first back wiring pattern 310 and the fifth source/drain region 165. The fifth gate structure GS5 may be interposed between the seventh source/drain contact 177 and the third back source/drain contact 303.

The first back wiring pattern 310 on the buffer cell BC may be connected to the sixth active pattern AP6. For example, a fourth back source/drain contact 304 that comes into contact with the sixth source/drain region 166 may be formed on one side of the sixth gate structure GS6. The fourth back source/drain contact 304 may penetrate the substrate 100 and connect the first back wiring pattern 310 and the sixth source/drain region 166. The sixth gate structure GS6 may be interposed between the eighth source/drain contact 178 and the fourth back source/drain contact 304.

The first back wiring pattern 310 on the buffer cell BC may be provided as a second power supply line that applies a second power supply voltage (e.g., V_{SS}) different from the first power supply voltage (e.g., V_{DD}) to the first buffer transistor BP1 and the second buffer transistor BP2.

In some embodiments, a fifth back source/drain contact 305 that comes into contact with the sixth source/drain region 166 may be further formed on one side of the eighth gate structure GS8. The fifth back source/drain contact 305 may penetrate the substrate 100, and connect the first back wiring pattern 310 and the sixth source/drain region 166. The eighth gate structure GS8 may be interposed between the eighth source/drain contact 178 and the fifth back source/drain contact 305. In some embodiments, the fifth back source/drain contact 305 of the buffer cell BC may be provided as the second back source/drain contact 302 of the adjacent memory cell MC.

In some embodiments, the first back wiring pattern 310 may include a first portion 310a and a second portion 310b that intersect each other.

The first portion 310a of the first back wiring pattern 310 may extend long in the first direction X. The first portion 310a on the memory cell MC may overlap the first back source/drain contact 301 in the third direction Z. That is, the first back source/drain contact 301 may connect the first portion 310a on the memory cell MC to the first active pattern AP1. The first portion 310a on the buffer cell BC may overlap the third back source/drain contact 303 in the third direction Z. That is, the third back source/drain contact 303 may connect the first portion 310a on the buffer cell BC to the fifth active pattern AP5.

The second portion 310b of the first back wiring pattern 310 may extend long in the second direction Y. The second portion 310b on the memory cell MC may overlap the second back source/drain contact 302 in the third direction Z. That is, the second back source/drain contact 302 may connect the second portion 310b on the memory cell MC to the fourth active pattern AP4. The second portion 310b on the buffer cell BC may overlap the fifth back source/drain contact 305 in the third direction Z. That is, the fifth back source/drain contact 305 may connect the second portion 310b on the buffer cell BC to the sixth active pattern AP6.

In some embodiments, the fourth back source/drain contact 304 may overlap a region of the first back wiring pattern 310 in which the first portion 310a and the second portion 310b intersect each other.

In some embodiments, the second level back wiring BM2 may include a second back wiring pattern 330 on the memory cell MC and the buffer cell BC. The second back wiring pattern 330 may extend long in the first direction X.

The second back wiring pattern 330 may be connected to the sixth front wiring pattern 230. For example, a through via (not shown) that penetrates the substrate 100 and electrically connects the sixth front wiring pattern 230 and the second back wiring pattern 330 may be formed. As the sixth front wiring pattern 230 provided as the word line WL is connected to the second back wiring pattern 330, the second back wiring pattern 330 may also be provided as the word line WL. That is, the word line WL may include a sixth front wiring pattern 230 extending in the first direction X on the first side 100a of the substrate 100, and a second back wiring pattern 330 extending in the first direction X on the second side 100b of the substrate 100.

In some embodiments, the second back wiring pattern 330 on the buffer cell BC may electrically float. In some embodiments, unlike the shown example, the second back wiring pattern 330 on the buffer cell BC may be omitted.

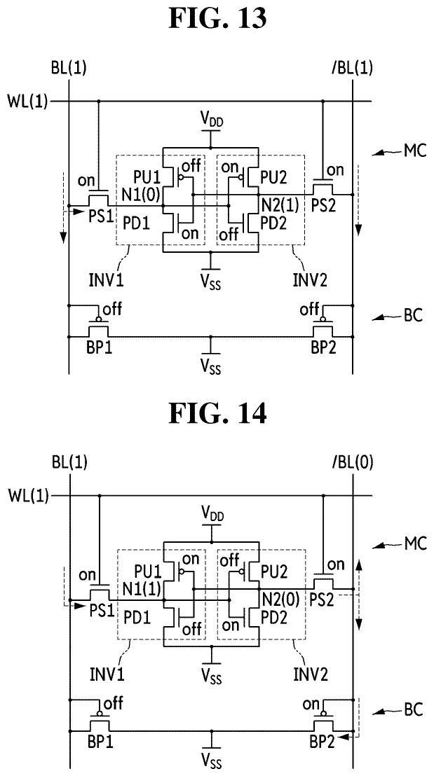

Hereinafter, the operation of the semiconductor device according to example embodiments will be described referring to FIGS. 13 and 14.

FIG. 13 is a circuit diagram for explaining a read operation of the semiconductor device according to some embodiments.

Referring to FIGS. 1 to 13, the read operation is performed on the memory cell MC selected by the word line WL, the bit line BL, and the complementary bit line /BL.

As an example, FIG. 13 shows that data (0, 1) is stored in the selected memory cell MC. Specifically, a first output node N1 of the first inverter INV1 may be set to a low level 0, and a second output node N2 of the second inverter INV2 may be set to a high level 1.

In order to perform the read operation on the selected memory cell MC, a voltage of high level 1 may be applied to each of the word line WL, the bit line BL, and the complementary bit line /BL.

As the voltage of high level 1 is applied to the word line WL, the first pass transistor PS1 which is an NFET, and the second pass transistor PS2 which is an NFET may be turned on.

In addition, as the first output node N1 of the first inverter INV1 has a low level 0, the second pull-up transistor PU2 which is a PFET may be provided in an on-state, and the second pull-down transistor PD2 may be provided in an off-state. That is, the second pass transistor PS2 may be connected to the power supply node V_{DD}, and the complementary bit line /BL connected to the second pass transistor PS2 may maintain a voltage of high level 1 by the power supply node V_{DD}.

In contrast, as the second output node N2 of the second inverter INV2 has a high level 1, the first pull-up transistor PU1 which is a PFET may be provided in an-off state, and the first pull-down transistor PD1 which is an NFET may be provided in an on-state. That is, the first pass transistor PS1 may be connected to the ground node V_{SS}, and a voltage drop due to the ground node V_{SS} may occur in the bit line BL connected to the first pass transistor PS1. That is, a voltage difference may occur between the bit line BL and the complementary bit line /BL.

A column decoder (e.g., 40 of FIG. 1) connected to the bit line BL and the complementary bit line /BL may detect and/or amplify a voltage difference between the bit line BL and the complementary bit line /BL. Accordingly, a read operation may be performed on the selected memory cell MC.

As the voltage of high level 1 is applied to each of the bit line BL and the complementary bit line /BL, each of the first buffer transistor BP1 which is a PFET, and the second buffer transistor BP2 which is a PFET may be turned off.

FIG. 14 is a circuit diagram for explaining a write operation of the semiconductor device according to some embodiments.

Referring to FIGS. 1 to 14, a write operation is performed on the memory cell MC selected by the word line WL, the bit line BL, and the complementary bit line /BL.

As an example, FIG. 14 shows that data (1, 0) are stored in the selected memory cell MC. Specifically, in order to perform the write operation on the selected memory cell MC, the voltage of high level 1 may be applied to each of the word line WL and the bit line BL, and a voltage of low level 0 may be applied to the complementary bit line /BL.

As the voltage of high level 1 is applied to the word line WL, the first pass transistor PS1 which is an NFET, and the second pass transistor PS2 which is an NFET may be turned on. Accordingly, the first output node N1 of the first inverter INV1 connected to the first pass transistor PS1 may be set to the high level 1, and the second output node N2 of the second inverter INV2 connected to the second pass transistor PS2 may be set to the low level 0.

Also, as the first output node N1 of the first inverter INV1 is set to the high level 1, the second pull-up transistor PU2 which is a PFET may be set in an off-state, and the second pull-down transistor PD2 which is an NFET may be provided in an on-state. That is, the second output node N2 of the second inverter INV2 may maintain the voltage of low level 0 by the ground node VSS.

Also, as the second output node N2 of the second inverter INV2 is set to the low level 0, the first pull-up transistor PU1 which is a PFET may be provided in an on-state, and the first pull-down transistor PD1 which is an NFET may be provided in an off-state. That is, the first output node N1 of the first inverter INV1 may maintain a voltage of high level 1 by the power supply node V_{DD}.

As the voltage of low level 0 is applied to the complementary bit line /BL, the second buffer transistor BP2 which is a PFET may be turned on. The complementary bit line /BL may be additionally connected to the ground node VSS through the second buffer transistor BP2. That is, the second buffer transistor BP2 may provide an additional electrical path connected to the ground node V_{SS} to the complementary bit line /BL to which the voltage of low level 0 is applied.

As the semiconductor devices gradually become highly integrated, individual circuit patterns are further miniaturized to implement more semiconductor devices in the same area. This causes a problem of deepening delay in the transmission of electrical signals through the wiring. For example, in a static random access memory (SRAM) element, when a voltage of low level is applied to the bit line, the voltage drop time increases due to the resistance of the miniaturized bit line.

The semiconductor device according to some embodiments may reduce a voltage drop time by using the buffer cell BC. Specifically, the buffer cell BC may include a first buffer transistor BP1 and a second buffer transistor BP2 that each operate according to voltages applied to the bit line BL and the complementary bit line /BL. For example, as mentioned above, when a voltage of low level 0 is applied to the complementary bit line /BL, the second buffer transistor BP2 may be turned on to form an additional electrical path connected to the ground node V_{SS} on the complementary bit line /BL. That is, when a voltage of low level 0 is applied to the complementary bit line /BL, the second buffer transistor BP2 may reduce the effective resistance of the complementary bit line /BL, thereby reducing the voltage drop time of the complementary bit line /BL. A semiconductor device with improved performance can be provided, accordingly.

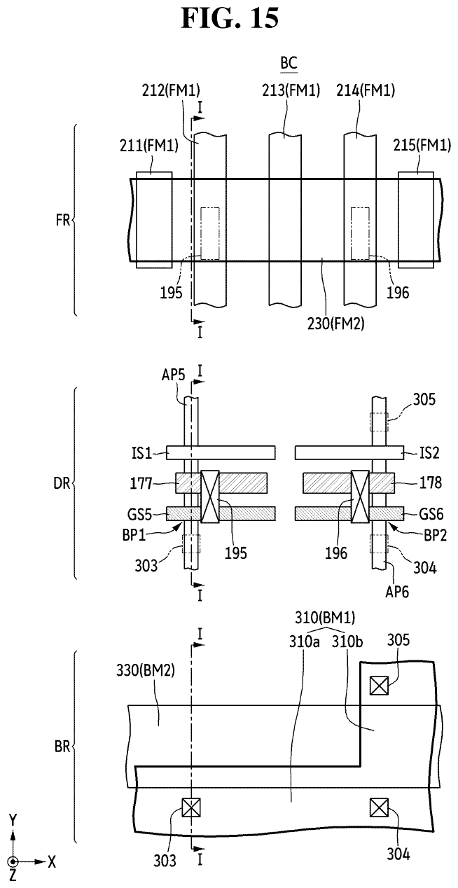

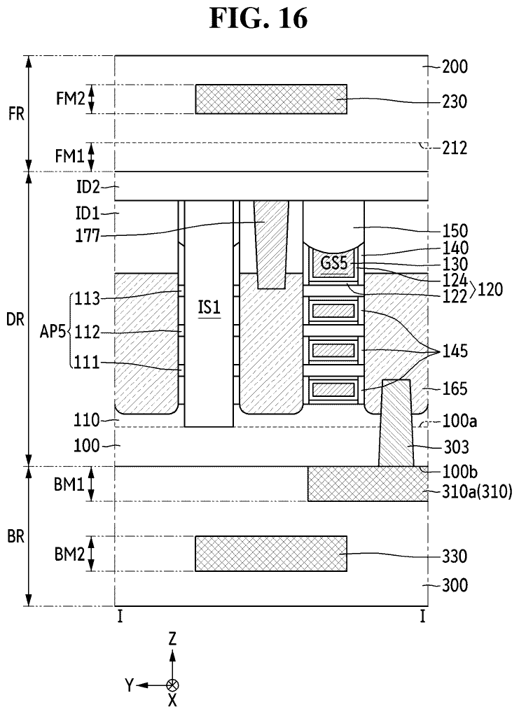

FIG. 15 is an example layout diagram for explaining a unit buffer cell of a semiconductor device according to some embodiments. FIG. 16 is a schematic cross-sectional view taken along I-I of FIG. 15. For convenience of explanation, repeated parts of contents explained using FIGS. 1 to 14 will be briefly described or omitted.

Referring to FIGS. 15 and 16, in the semiconductor device according to some embodiments, the buffer cell BC includes a first insulating structure IS1 and a second insulating structure IS2.

The first insulating structure IS1 may be spaced apart from the fifth gate structure GS5 in the second direction Y. The first insulating structure IS1 may intersect the fifth active pattern AP5. For example, the first insulating structure IS1 may replace the seventh gate structure GS7 explained above using FIGS. 8 to 12.

The second insulating structure IS2 may be spaced apart from the sixth gate structure GS6 in the second direction Y. The second insulating structure IS2 may intersect the sixth active pattern AP6. For example, the second insulating structure IS2 may replace the eighth gate structure GS8 explained above using FIGS. 8 to 12.

In some embodiments, the first insulating structure IS1 may be interposed between the memory cell MC and the fifth gate structure GS5. The first insulating structure IS1 may be used to enhance an electrical isolation between the memory cell MC and the first buffer transistor BP1.

In some embodiments, the second insulating structure IS2 may be interposed between the memory cell MC and the sixth gate structure GS6. The second insulating structure IS2 may be used to enhance the electrical isolation between the memory cell MC and the second buffer transistor BP2.

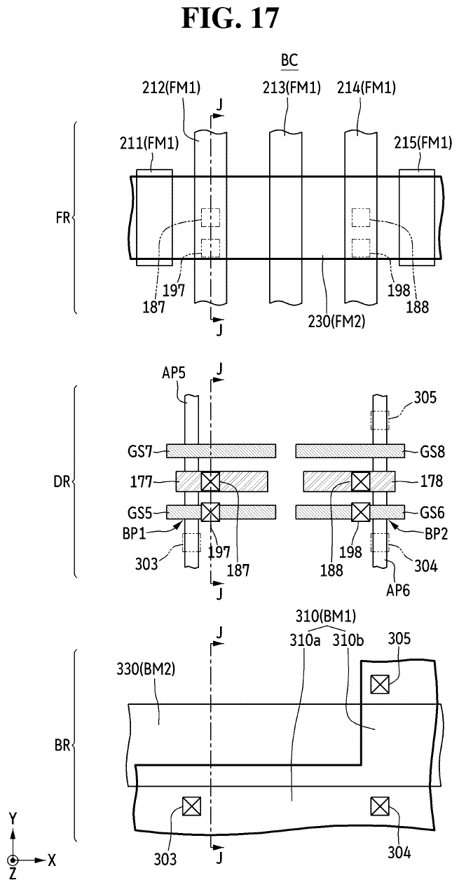

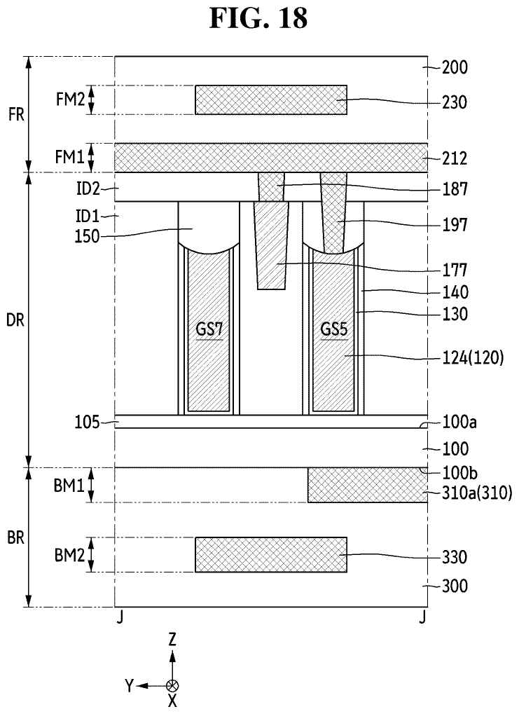

FIG. 17 is an example layout diagram for explaining a unit buffer cell of a semiconductor device according to some embodiments. FIG. 18 is a schematic cross-sectional view taken along J-J of FIG. 17. For convenience of explanation, repeated parts of contents explained using FIGS. 1 to 14 will be briefly explained or omitted.

Referring to FIGS. 17 and 18, in the semiconductor device according to some embodiments, the buffer cell BC includes a fifth contact via 187, a sixth contact via 188, a third gate contact 197, and a fourth gate contact 198.

The fifth contact via 187 may penetrate the second interlayer insulating film ID2 and come into contact with the seventh source/drain contact 177. The second front wiring pattern 212 may be electrically connected to the seventh source/drain contact 177 through the fifth contact via 187.

The third gate contact 197 penetrates the second interlayer insulating film ID2 and the gate capping film 150, and may come into contact with the gate electrode 130 of the fifth gate structure GS5. The second front wiring pattern 212 may be electrically connected to the gate electrode 130 of the fifth gate structure GS5 through the third gate contact 197.

The fifth gate structure GS5 and the seventh source/drain contact 177 may be electrically connected through the fifth contact via 187 and the third gate contact 197. Therefore, the source and gate of the first buffer transistor BP1 may have the same potential.

The sixth contact via 188 penetrates the second interlayer insulating film ID2, and may come into contact with the eighth source/drain contact 178. The fourth front wiring pattern 214 may be electrically connected to the eighth source/drain contact 178 through the sixth contact via 188.

The fourth gate contact 198 penetrates the second interlayer insulating film ID2 and the gate capping film 150, and may come into contact with the gate electrode 130 of the sixth gate structure GS6. The fourth front wiring pattern 214 may be electrically connected to the gate electrode 130 of the sixth gate structure GS6 through the fourth gate contact 198.

The sixth gate structure GS6 and the eighth source/drain contact 178 may be electrically connected through the sixth contact via 188 and the fourth gate contact 198. Thus, the source and gate of the second buffer transistor BP2 may have the same potential.

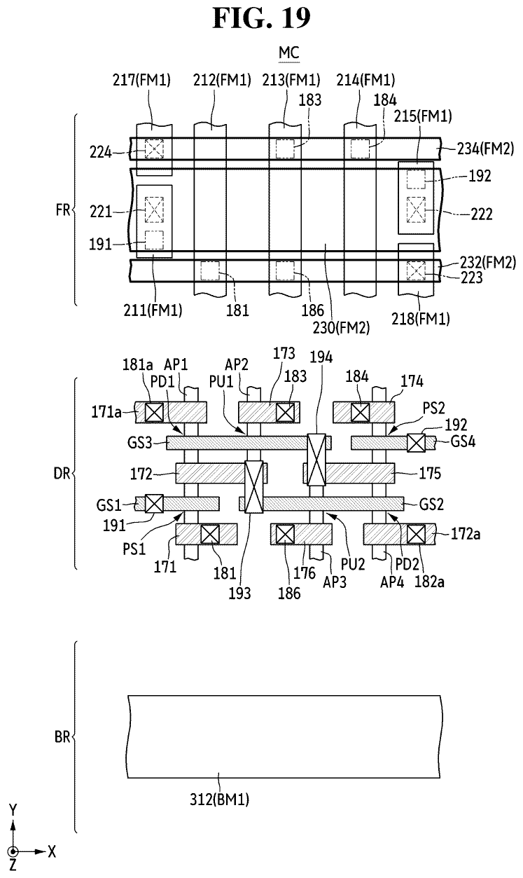

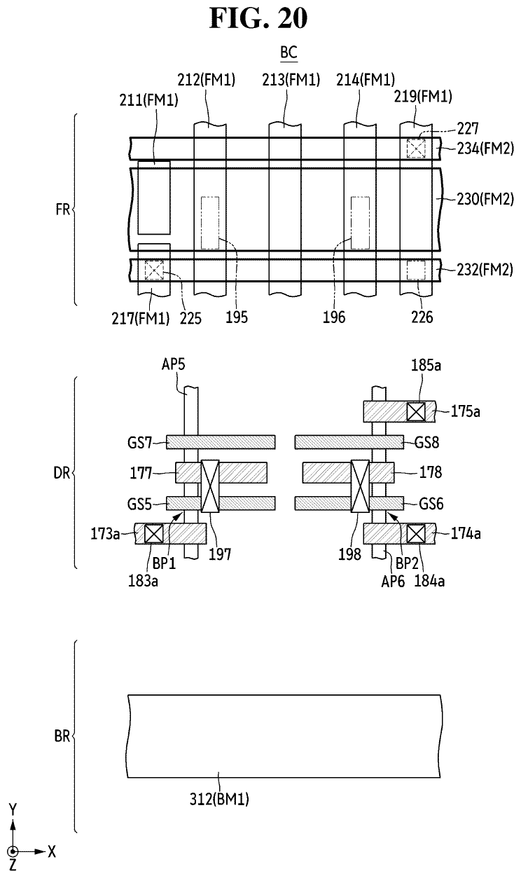

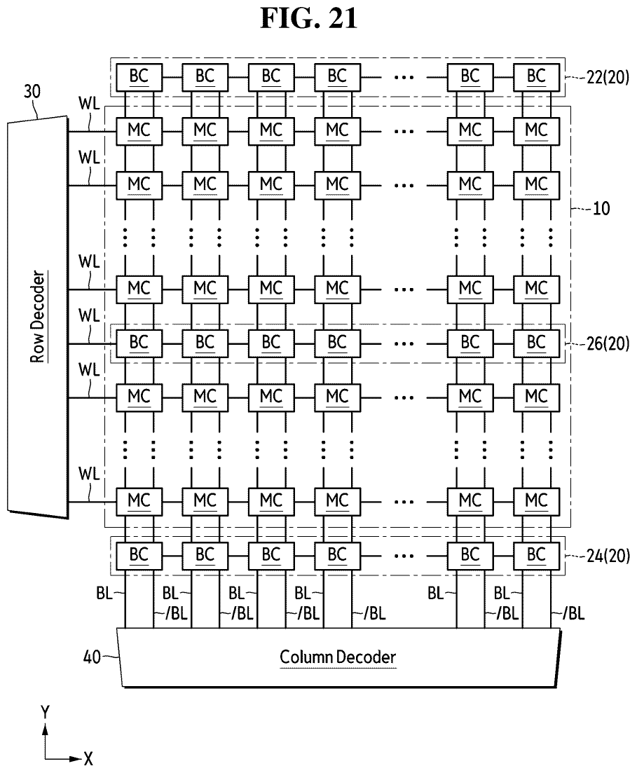

FIG. 19 is an example layout diagram for explaining a unit memory cell of the semiconductor device according to some embodiments. FIG. 20 is an example layout diagram for explaining the unit buffer cell of the semiconductor device according to some embodiments. For convenience of explanation, repeated parts of contents explained using FIGS. 1 to 14 will be briefly explained or omitted.

Referring to FIGS. 19 and 20, in the semiconductor device according to some embodiments, the first level front wiring FM1 further includes a seventh front wiring pattern 217, an eighth front wiring pattern 218 and a ninth front wiring pattern 219, the second level front wiring FM2 further includes a tenth front wiring pattern 232 and an eleventh front wiring pattern 234, and the first level back wiring BM1 includes a third back wiring pattern 312.

The seventh front wiring pattern 217 on the memory cell MC may be connected to the first active pattern AP1. For example, a ninth source/drain contact 171a that comes into contact with the first source/drain region 161 may be formed on one side of the third gate structure GS3. The third gate structure GS3 may be interposed between the second source/drain contact 172 and the ninth source/drain contact 171a. The seventh front wiring pattern 217 may be connected to the ninth source/drain contact 171a. For example, a seventh contact via 181a that penetrates the second interlayer insulating film ID2 and comes into contact with the ninth source/drain contact 171a may be formed. The seventh front wiring pattern 217 may be electrically connected to the ninth source/drain contact 171a through the seventh contact via 181a. In some embodiments, the seventh front wiring pattern 217 may be arranged along the second direction Y together with the first front wiring pattern 211.

The eighth front wiring pattern 218 on the memory cell MC may be connected to the fourth active pattern AP4. For example, a tenth source/drain contact 172a that comes into contact with the fourth source/drain region 164 may be formed on one side of the second gate structure GS2. The second gate structure GS2 may be interposed between the fifth source/drain contact 175 and the tenth source/drain contact 172a. The eighth front wiring pattern 218 may be connected to the tenth source/drain contact 172a. For example, an eighth contact via 182a that penetrates the second interlayer insulating film ID2 and comes into contact with the tenth source/drain contact 172a may be formed. The eighth front wiring pattern 218 may be connected to the tenth source/drain contact 172a through the eighth contact via 182a. In some embodiments, the eighth front wiring pattern 218 may be arranged along the second direction Y together with the fifth front wiring pattern 215.

The seventh front wiring pattern 217 on the buffer cell BC may be connected to the fifth active pattern AP5. For example, an eleventh source/drain contact 173a that comes into contact with the fifth source/drain region 165 may be formed. The seventh front wiring pattern 217 may be connected to the eleventh source/drain contact 173a. For example, a ninth contact via 183a that comes into contact with the eleventh source/drain contact 173a may be formed. The seventh front wiring pattern 217 may be electrically connected to the eleventh source/drain contact 173a through the ninth contact via 183a.

The ninth front wiring pattern 219 may be connected to the sixth active pattern AP6. For example, a twelfth source/drain contact 174a and a thirteenth source/drain contact 175a that come into contact with the sixth source/drain region 166 may be formed. The ninth front wiring pattern 219 may be connected to the twelfth source/drain contact 174a and the thirteenth source/drain contact 175a. For example, a tenth contact via 184a and an eleventh contact via 185a that come into contact with the twelfth source/drain contact 174a and the thirteenth source/drain contact 175a may be formed. The ninth front wiring pattern 219 may be connected to the twelfth source/drain contact 174a and the thirteenth source/drain contact 175a through the tenth contact via 184a and the eleventh contact via 185a. In some embodiments, the ninth front wiring pattern 219 may extend long in the second direction Y.

The tenth front wiring pattern 232 on the memory cell MC may extend long in the first direction X. The tenth front wiring pattern 232 may be connected to the eighth front wiring pattern 218. For example, a third front via pattern 223 that connects the eighth front wiring pattern 218 and the tenth front wiring pattern 232 may be formed inside the front inter-wiring insulating film 200. The tenth front wiring pattern 232 may be provided as a second power supply line that applies the second power supply voltage (e.g., V_{SS}) to the second pull-down transistor PD2.

The eleventh front wiring pattern 234 on the memory cell MC may extend long in the first direction X. The eleventh front wiring pattern 234 may be connected to the seventh front wiring pattern 217. For example, a fourth front via pattern 224 that connects the seventh front wiring pattern 217 and the eleventh front wiring pattern 234 may be formed inside the front inter-wiring insulating film 200. The eleventh front wiring pattern 234 may be provided as a second power supply line that applies a second power supply voltage (e.g., V_{SS}) to the first pull-down transistor PD1.

The tenth front wiring pattern 232 on the buffer cell BC may extend long in the first direction X. The tenth front wiring pattern 232 may be connected to the seventh front wiring pattern 217 and the ninth front wiring pattern 219. For example, a fifth front via pattern 225 that connects the seventh front wiring pattern 217 and the tenth front wiring pattern 232, and a sixth front via pattern 226 that connects the ninth front wiring pattern 219 and the tenth front wiring pattern 232 may be formed. The tenth front wiring pattern 232 may be provided as a second power supply line that applies the second power supply voltage (e.g., V_{SS}) to the first buffer transistor BP1 and the second buffer transistor BP2.

The eleventh front wiring pattern 234 on the buffer cell BC may extend long in the first direction X. The eleventh front wiring pattern 234 may be connected to the ninth front wiring pattern 219. For example, a seventh front via pattern 227 that connects the ninth front wiring pattern 219 and the eleventh front wiring pattern 234 may be formed. The eleventh front wiring pattern 234 may be provided as a second power supply line that applies a second power supply voltage (e.g., V_{SS}) to the second buffer transistor BP2.

The third back wiring pattern 312 may be connected to the sixth front wiring pattern 230. For example, a through via (not shown) that penetrates the substrate 100 and electrically connects the sixth front wiring pattern 230 and the third back wiring pattern 312 may be formed. As the sixth front wiring pattern 230 provided as the word line WL is connected to the third back wiring pattern 312, the third back wiring pattern 312 may also be provided as the word line WL. That is, the word line WL may include a sixth front wiring pattern 230 extending in the first direction X on the first side 100a of the substrate 100, and a third back wiring pattern 312 extending in the first direction X on the second side 100b of the substrate 100.

In some embodiments, the third back wiring pattern 312 on the buffer cell BC may electrically float. In some embodiments, unlike the shown example, the third back wiring pattern 312 on the buffer cell BC may be omitted.

FIG. 21 is an example block diagram for explaining a semiconductor device according to some embodiments. For convenience of explanation, repeated parts of contents explained using FIGS. 1 to 20 will be briefly explained or omitted.

Referring to FIG. 21, in the semiconductor device according to some embodiments, the buffer cell region 20 further includes a third buffer cell region 26.

The third buffer cell region 26 may be disposed inside the cell array region 10. For example, the third buffer cell region 26 may be interposed between some of the plurality of memory cells MC and the column decoder 40, and another part of the memory cells MC may be interposed between the column decoder 40 and the third buffer cell region 26. In some embodiments, some of the plurality of memory cells MC may be interposed between the first buffer cell region 22 and the third buffer cell region 26. In some embodiments, some others of the plurality of memory cells MC may be interposed between the second buffer cell region 24 and the third buffer cell region 26. The third buffer cell region 26 may include a plurality of buffer cells BC arranged along the first direction X.

Although FIG. 21 only shows that the third buffer cell region 26 is disposed at the center of the cell array region 10, this is merely an example. As another example, it goes without saying that the third buffer cell region 26 may be closer to the first buffer cell region 22 or may be closer to the second buffer cell region 24.

In addition, although FIG. 21 only shows that one third buffer cell region 26 is disposed in the cell array region 10, this is merely an example. As another example, it goes without saying that a plurality of third buffer cell regions 26 arranged along the second direction Y may be disposed in the cell array region 10. The plurality of third buffer cell regions 26 may be spaced apart from each other in the second direction Y, or may be adjacent to each other in the second direction Y.

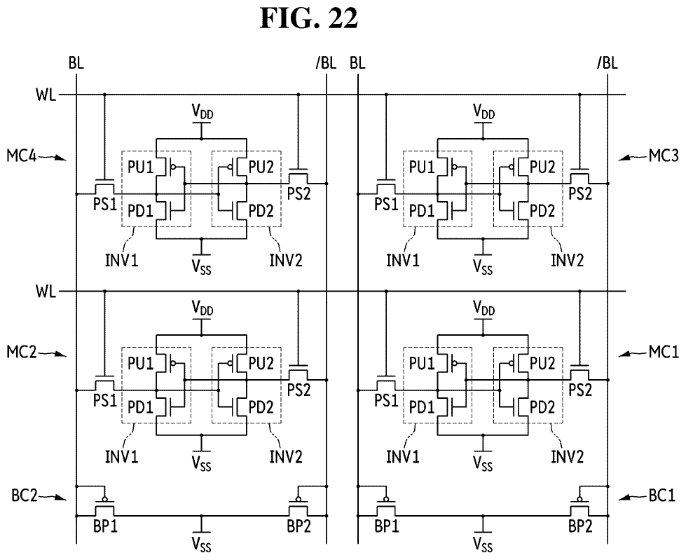

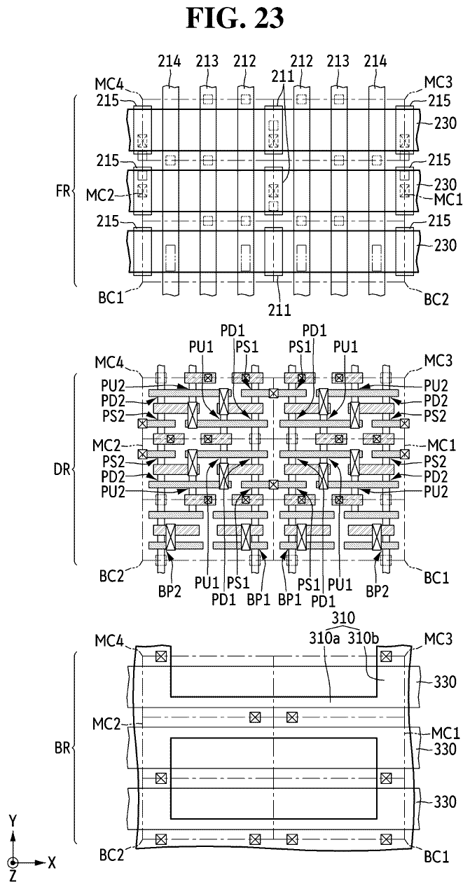

FIG. 22 is a circuit diagram for explaining a semiconductor device according to some embodiments. FIG. 23 is an example layout for explaining the semiconductor device of FIG. 22. For convenience of explanation, repeated parts of contents explained using FIGS. 1 to 21 will be briefly explained or omitted.

Referring to FIG. 22, the semiconductor device according to some embodiments includes first to fourth memory cells MC1 to MC4, a first buffer cell BC1, and a second buffer cell BC2 that are adjacent to each other.

Each of the first to fourth memory cells MC1 to MC4 may be an SRAM unit cell. For example, each of the first to fourth memory cells MC1 to MC4 may include a pair of inverters INV1 and INV2 connected in parallel between the power supply node V_{DD} and the ground node V_{SS}, and a first pass transistor PS1 and a second pass transistor PS2 connected to the output node of each of the inverters INV1 and INV2. Because each of the first to fourth memory cells MC1 to MC4 is the same as that described above using FIG. 2, the detailed description thereof will not be provided below.

In some embodiments, the first memory cell MC1 and the second memory cell MC2 may share one word line WL, and the third memory cell MC3 and the fourth memory cell MC4 may share another word line WL. For example, the gates of the pass transistors PS1 and PS2 of the first memory cell MC1 and the gates of the pass transistors PS1 and PS2 of the second memory cell MC2 may be commonly connected to one word line WL. Also, the gates of the pass transistors PS1 and PS2 of the third memory cell MC3 and the gates of the pass transistors PS1 and PS2 of the fourth memory cell MC4 may be commonly connected to the other word line WL.

In some embodiments, the first memory cell MC1, the third memory cell MC3, and the first buffer cell BC1 may share one bit line BL and one complementary bit line /BL. For example, the first pass transistor PS1 of the first memory cell MC1, the first pass transistor PS1 of the third memory cell MC3, and the first buffer transistor BP1 of the first buffer cell BC1 may be commonly connected to one bit line BL. Also, the second pass transistor PS2 of the first memory cell MC1, the second pass transistor PS2 of the third memory cell MC3, and the second buffer transistor BP2 of the first buffer cell BC1 may be commonly connected to one complementary bit line /BL.

In some embodiments, the second memory cell MC2, the fourth memory cell MC4, and the second buffer cell BC2 may share the other bit line BL and the other complementary bit line /BL. For example, the first pass transistor PS1 of the second memory cell MC2, the first pass transistor PS1 of the fourth memory cell MC4, and the first buffer transistor BP1 of the second buffer cell BC2 may be commonly connected to another bit line BL. Also, the second pass transistor PS2 of the second memory cell MC2, the second pass transistor PS2 of the fourth memory cell MC4, and the second buffer transistor BP2 of the second buffer cell BC2 may be commonly connected to another complementary bit line /BL.

Referring to FIGS. 22 and 23, the semiconductor device according to some embodiments includes first to fourth memory cells MC1 to MC4, a first buffer cell BC1, and a second buffer cell BC2.

Each of the first to fourth memory cells MC1 to MC4 of FIG. 23 is the same as those explained above using FIGS. 3 to 7, and therefore detailed description thereof will not be provided. Further, each of the first and second buffer cells BC1 and BC2 of FIG. 23 is the same as those explained above using FIGS. 8 to 12, and therefore detailed description thereof will not be provided.

The first memory cell MC1 and the second memory cell MC2 may be arranged in a plane-symmetric relationship with respect to a plane intersecting the first direction X (e.g., an YZ plane). The third memory cell MC3 and the fourth memory cell MC4 may be arranged in a plane-symmetric relationship with respect to the plane intersecting the first direction X (e.g., the YZ plane). The first memory cell MC1 and the third memory cell MC3 may be arranged in a plane-symmetric relationship with respect to a plane intersecting the second direction Y (e.g., a XZ plane). The second memory cell MC2 and the fourth memory cell MC4 may be arranged in a plane-symmetric relationship with respect to the plane intersecting the second direction Y (that is, the XZ plane).

The second front wiring pattern 212 and the fourth front wiring pattern 214 may be repeatedly arranged in the first direction X. One second front wiring pattern 212 extends in the second direction Y, and may be provided as a bit line BL commonly connected to the first memory cell MC1, the third memory cell MC3, and the first buffer cell BC1. The other second front wiring pattern 212 extends in the second direction Y, and may be provided as another bit line BL commonly connected to the second memory cell MC2, the fourth memory cell MC4, and the second buffer cell BC2. One fourth front wiring pattern 214 extends in the second direction Y, and may be provided as a single complementary bit line /BL commonly connected to the first memory cell MC1, the third memory cell MC3, and the first buffer cell BC1. The other fourth front wiring pattern 214 extends in the second direction Y, and may be provided as another complementary bit line /BL commonly connected to the second memory cell MC2, the fourth memory cell MC4, and the second buffer cell BC2.

The third front wiring pattern 213 may be repeatedly arranged in the first direction X. One third front wiring pattern 213 extends in the second direction Y, and may be provided as a first power supply line that applies the first power supply voltage (e.g., V_{DD}) to the first memory cell MC1 and the third memory cell MC3. The other third front wiring pattern 213 extends in the second direction Y, and may be provided as a first power supply line that applies the first power supply voltage (e.g., V_{DD}) to the second memory cell MC2 and the fourth memory cell MC4.

The sixth front wiring pattern 230 may be repeatedly arranged in the second direction Y.

One sixth front wiring pattern 230 extends in the first direction X, and may be provided as a single word line WL commonly connected to the first memory cell MC1 and the second memory cell MC2. For example, the single sixth front wiring pattern 230 may be shared by the first memory cell MC1 and the second memory cell MC2 through the first front wiring pattern 211 and the fifth front wiring pattern 215. In some embodiments, the first memory cell MC1 and the second memory cell MC2 may share the single first front wiring pattern 211.

The other sixth front wiring pattern 230 extends in the first direction X, and may be provided as the other word line WL that is commonly connected to the third memory cell MC3 and the fourth memory cell MC4. For example, the other sixth front wiring pattern 230 may be shared by the third memory cell MC3 and the fourth memory cell MC4 through the first front wiring pattern 211 and the fifth front wiring pattern 215. In some embodiments, the third memory cell MC3 and the fourth memory cell MC4 may share the other first front wiring pattern 211.

The first back wiring pattern 310 may be provided as a second power supply line that applies the second power supply voltage (e.g., V_{SS}) to the first to fourth memory cells MC4, the first buffer cell BC1, and the second buffer cell BC2. In some embodiments, the first back wiring pattern 310 may be commonly connected to the first to fourth memory cells MC4, the first buffer cell BC1, and the second buffer cell BC2. For example, as shown in FIG. 23, the first back wiring pattern 310 including the first portion 310a and the second portion 310b may extend continuously over the first to fourth memory cells MC4, the first buffer cell BC1 and the second buffer cell BC2. Such a first back wiring pattern 310 may provide a mesh-shaped wiring pattern over the cell array region 10 and the buffer cell region 20.

The second back wiring pattern 330 may be repeatedly arranged in the second direction Y. One second back wiring pattern 330 may be connected to one sixth front wiring pattern 230. The other second back wiring pattern 330 may be connected to the other sixth front wiring pattern 230.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts has been particularly shown and described with reference to example embodiments thereof, it will be understood by those of ordinary skill in the art that various changes in form and details may be made therein without departing from the spirit and scope of inventive concepts as defined by the following claims. It is therefore desired that the present embodiments be considered in all respects as illustrative and not restrictive, reference being made to the appended claims rather than the foregoing description to indicate the scope of inventive concepts.

What is claimed is:

1. A semiconductor device comprising:
a substrate;
a first power supply line and a second power supply line on the substrate and configured to have different voltages applied thereto;
a word line extending in a first direction on the substrate;
a bit line and a complementary bit line extending in a second direction on the substrate, the second direction intersecting the first direction; and
a first cell and a second cell are arranged along the second direction on the substrate, wherein
the first cell includes a latch circuit, a first pass transistor, and a second pass transistor,
the latch circuit includes a first inverter and a second inverter connected in parallel between the first power supply line and the second power supply line,
the first pass transistor connects an output node of the first inverter to the bit line,
the second pass transistor connects an output node of the second inverter to the complementary bit line,
the word line is connected to a gate of the first pass transistor and a gate of the second pass transistor,
the second cell includes a first buffer transistor and a second buffer transistor,
the first buffer transistor connects the second power supply line and the bit line,
the second buffer transistor connects the second power supply line to the complementary bit line,
the bit line is connected to a gate of the first buffer transistor, and
the complementary bit line is connected to a gate of the second buffer transistor.

2. The semiconductor device of claim 1,
wherein each of the first buffer transistor and the second buffer transistor is a PFET.

3. The semiconductor device of claim 1,
wherein the second power supply line is configured to have a ground voltage applied thereto.

4. The semiconductor device of claim 1,
wherein a first side of the substrate is opposite a second side of the substrate, and
each of the word line, the bit line, and the complementary bit line is on the first side.

5. The semiconductor device of claim 4, wherein
the word line is spaced apart from the substrate farther than each of a distance in which the bit line is spaced apart from the substrate and a distance in which the complementary bit line is spaced apart from the substrate.

6. The semiconductor device of claim 1,
wherein a first side of the substrate is opposite a second side of the substrate,
the first power supply line is on the first side, and
the second power supply line is on the second side.

7. The semiconductor device of claim 6, wherein
a first portion of the second power supply line extends in the first direction, and
a second portion of the second power supply line extends in the second direction.

8. The semiconductor device of claim 6,
wherein the bit line, the complementary bit line, and the first power supply line are disposed at a same level.

9. The semiconductor device of claim 6, wherein
the word line is spaced apart from the substrate farther than a distance in which the first power supply line is spaced apart from substrate.

10. The semiconductor device of claim 1,
wherein a first side of the substrate is opposite a second side of the substrate,
the word line includes a front wiring pattern on the first side and a back wiring pattern on the second side.

11. A semiconductor device comprising:
a cell array region including a plurality of SRAM unit cells, the plurality of SRAM unit cells arranged in a matrix form along a first direction and a second direction that intersect each other;
a word line commonly connected to one row of SRAM unit cells in the first direction among the plurality of SRAM unit cells;
a bit line commonly connected to one column of SRAM unit cells in the second direction among the plurality of SRAM unit cells;
a complementary bit line commonly connected to the one column of SRAM unit cells; and
a buffer cell region arranged along the cell array region, wherein
the buffer cell region includes a p-type first buffer transistor connecting the bit line to a ground node, and a p-type second buffer transistor connecting ts the complementary bit line to the ground node,
the bit line is connected to a gate of the p-type first buffer transistor, and
the complementary bit line is connected to a gate of the p-type second buffer transistor.

12. The semiconductor device of claim 11, wherein
each of the SRAM unit cells includes a first inverter, a second inverter, a first pass transistor, and a second pass transistor,
the first inverter and the second inverter are connected in parallel between a power supply node and the ground node to form one latch circuit,
the first pass transistor connects an output node of the first inverter to the bit line, the second pass transistor connects an output node of the second inverter to a complementary bit line, and
the word line is connected to a gate of the first pass transistor and a gate of the second pass transistor.

13. The semiconductor device of claim 11, wherein
a first side of the cell array region is opposite a second side of the cell array region in the second direction, and
the buffer cell region is on the first side of the cell array region, the second side of the cell array region, or both the first side of cell array region and the second side of the cell array region.

14. The semiconductor device of claim 11, further comprising:
a column decoder connected to the cell array region through the bit line and the complementary bit line, wherein
the buffer cell region includes a first buffer cell region and a second buffer cell region,
the first buffer cell region is between the cell array region and the column decoder, and
the cell array region is between the first buffer cell region and the second buffer cell region.

15. The semiconductor device of claim 14, wherein
the buffer cell region further includes a third buffer cell region inside the cell array region.

16. A semiconductor device, which includes a first cell and a second cell arranged along a first direction, the semiconductor device comprising:
a substrate including a first side and a second side opposite each other;
a first active pattern, a second active pattern, a third active pattern, and a fourth active pattern, which are sequentially arranged in the first direction on a first side of the first cell, each of the first active pattern, the second active pattern, the third active pattern, and the fourth active pattern extending in a second direction, the second direction intersecting the first direction;
a first gate structure extending in the first direction and intersecting the first active pattern;
a second gate structure extending in the first direction and intersecting the third active pattern and the fourth active patterns;
a third gate structure extending in the first direction and intersecting the first active pattern and the second active pattern;
a fourth gate structure extending in the first direction and intersecting the fourth active pattern;
a first source/drain contact connected to the first active pattern on a side face of the first gate structure;
a second source/drain contact connecting the first active pattern and the second active pattern to each other, the first gate structure being between the second source/drain contact and the first source/drain contact;
a first shared contact connecting the second gate structure and the second source/drain contact to each other;
a third source/drain contact connected to the fourth active pattern on a side face of the fourth gate structure;
a fourth source/drain contact connecting the third active pattern and the fourth active pattern to each other, the fourth gate structure being between the fourth source/drain contact and the third source/drain contact;
a second shared contact connecting the third gate structure and the fourth source/drain contact to each other;
a fifth active pattern extending in the second direction on a first side of the second cell;
a fifth gate structure extending in the first direction and intersecting the fifth active pattern;
a fifth source/drain contact connected to the fifth active pattern and on a side face of the fifth gate structure;
a third shared contact connecting the fifth gate structure and the fifth source/drain contact; and
a first front wiring pattern extending in the second direction on the first side of the substrate, the first front wiring pattern being connected to the first source/drain contact and the third shared contact.

17. The semiconductor device of claim 16,
wherein each of the first active pattern and the fourth active pattern includes a channel region of an NFET, and
each of the second active pattern, the third active pattern, and the fifth active pattern includes a channel region of a PFET.

18. The semiconductor device of claim 16, comprising:
a sixth active pattern extending in the second direction on the first side of the second cell;
a sixth gate structure which extends in the first direction and intersects the sixth active pattern;
a sixth source/drain contact connected to the sixth active pattern and on a side face of the sixth gate structure;
a fourth shared contact connecting the sixth gate structure and the sixth source/drain contact to each other; and
a second front wiring pattern extending in the second direction on the first side of the substrate, the second front wiring pattern being connected to the third source/drain contact and the fourth shared contact.

19. The semiconductor device of claim 18, further comprising:
a seventh source/drain contact connected to the first active pattern, the third gate structure being between the seventh source/drain contact and the second source/drain contact;
an eighth source/drain contact connected to the fourth active pattern, the second gate structure being between the eighth source/drain contact and the fourth source/drain contact;
a ninth source/drain contact connected to the fifth active pattern, the fifth gate structure being between the ninth source/drain contact and the fifth source/drain contact; and
a tenth source/drain contact connected to the sixth active pattern, the sixth gate structure being between the tenth source/drain contact and the sixth source/drain contact,
wherein the seventh source/drain contact, the eight source/drain contact, the ninth source/drain contact, and the tenth source/drain contact are electrically connected to each other.

20. The semiconductor device of claim 19, further comprising:
a back wiring pattern on the second side of the substrate and configured to have a ground voltage applied thereto,
wherein each of the seventh source/drain contact, the eight source/drain contact, the ninth source/drain contact, and the tenth source/drain contact penetrates the substrate and is connected to the back wiring pattern.
